(19) United States
(12) Patent Application Publication
(10) Pub. No.: US 2025/0107350 A1
(43) Pub. Date: Mar. 27, 2025

(54) DISPLAY DEVICE

(71) Applicant: Samsung Display Co., LTD., Yongin-si (KR)

(72) Inventors: Chul Min BAE, Yongin-si (KR); Jae Hee SEO, Yongin-si (KR); Ji Hye HAN, Yongin-si (KR)

(21) Appl. No.: 18/893,351

(22) Filed: Sep. 23, 2024

(30) Foreign Application Priority Data
Sep. 25, 2023 (KR) 10-2023-0128129

(51) Int. Cl. H10K 59/122

(52) U.S. Cl. CPC H10K 59/122

(57) ABSTRACT

A display device includes a first pixel electrode on a substrate, a first light emitting layer on the first pixel electrode, a first common electrode on the first light emitting layer, a first bank on the substrate and exposing the first common electrode therethrough, and a second bank on the first bank and having side surfaces protruding beyond side surfaces of the first bank. A width of a lower surface of the first bank is smaller than that of an upper surface of the first bank.

### CROSS-REFERENCE TO RELATED APPLICATION

The present application claims priority to and the benefit of from Korean Patent Application No. 10-2023-0128129, filed on Sep. 25, 2023, in the Korean Intellectual Property Office, the entire disclosure of which is incorporated herein by reference.

### BACKGROUND

### 1. Field

Aspects of embodiments of the present disclosure relate to a display device.

### 2. Description of the Related Art

With the advancement of the information age, the demand for a display device for displaying an image in various forms has increased. For example, the display device has been applied to various electronic devices, such as a smart phone, a digital camera, a laptop computer, a navigation device, and a smart television. The display device may be a flat panel display device, such as a liquid crystal display device, a field emission display device, and an organic light emitting display device. From among the flat panel display devices, a light emitting display device includes a light emitting element in which each pixel in a display panel may self-emit light (e.g., each pixel may be self-emissive), thereby displaying an image without requiring a backlight unit that provides the display panel with light.

Recently, the display device has been applied to a glasses-type device to provide virtual reality (VR) and augmented reality (AR). To be applied to the glasses-type device, the display device is implemented at a very small size of about 2 inches or less. However, the display device should have high pixel integration so that the display device may provide images at high resolution. For example, the display device may have high pixel integration of about 400 pixels per inch (PPI) or more.

As described above, the display device is implemented at a very small size, but an area of a light emission area in which a light emitting element is disposed is reduced when the display device has high pixel integration. Therefore, it is difficult to implement light emitting elements separated at each light emission area by a mask process.

### SUMMARY

Embodiments of the present disclosure provide a display device having light emitting elements separated for each light emission area formed without a mask process.

Embodiments of the present disclosure also provide a display device in which a light emission deviation that may occur in each pixel is reduced.

Aspects and features of the present disclosure are not limited to those mentioned above and additional aspects and features of the present disclosure, which are not mentioned herein, will be clearly understood by those skilled in the art from the following description of the present disclosure.

According to an embodiment of the present disclosure, a display device includes: a first pixel electrode on a substrate; a first light emitting layer on the first pixel electrode; a first common electrode on the first light emitting layer; a first bank on the substrate and exposing the first common electrode therethrough; and a second bank on the first bank and having side surfaces protruding beyond side surfaces of the first bank. A width of a lower surface of the first bank is smaller than that of an upper surface of the first bank.

The first common electrode may be in contact with the side surfaces of the first bank.

An angle between the lower surface and the side surfaces of the first bank may be greater than 90°.

The first bank may include at least one of polysilicon, amorphous carbon, graphite, and graphene.

The second bank may include at least one of SiOₓ, SiN_{y}, SiOₓN_{y}, and a metal.

The display device may further include an auxiliary electrode between the substrate and the first bank.

The auxiliary electrode may be in contact with the first common electrode.

The display device may further include: a third bank on the second bank; and a fourth bank on the third bank. The fourth bank may have side surfaces protruding beyond side surfaces of the third bank.

A width of a lower surface of the third bank may be smaller than a width of an upper surface of the third bank and smaller than a width of the second bank.

The display device may further include a first inorganic layer on the second bank and the first common electrode.

The display device may further include a first capping layer between the first common electrode and the first inorganic layer.

The display device may further include: a second pixel electrode on the substrate and spaced apart from the first pixel electrode; a second light emitting layer on the second pixel electrode; a second common electrode on the second light emitting layer and spaced apart from the first common electrode; and a second inorganic layer on the second common electrode and the second bank and spaced apart from the first inorganic layer.

The display device may further include: a first light emitting pattern between the second bank and the first inorganic layer and may include the same material as that of the first light emitting layer; and a first electrode pattern between the first light emitting pattern and the first inorganic layer and may include the same material as that of the first common electrode.

According to an embodiment of the present disclosure, a display device include: a first pixel electrode on a substrate; a first light emitting layer on the first pixel electrode; a first common electrode on the first light emitting layer; a first bank on the substrate and exposing the first common electrode therethrough; and a second bank on the first bank and having side surfaces protruding beyond side surfaces of the first bank. The first bank includes at least one of polysilicon, amorphous carbon, graphite, and graphene, and the first common electrode is in contact with the side surfaces of the first bank.

The second bank includes at least one of SiOₓ, SiN_{y}, SiOₓN_{y}, and a metal.

The display device may further include a first inorganic layer on an upper surface of the first common electrode, the side surfaces of the first bank, and an upper surface and a lower surface of the second bank.

According to an embodiment of the present disclosure, a display device includes: a first pixel electrode on a substrate; a pixel defining layer on the substrate and exposing the first pixel electrode therethrough; a first light emitting layer on the first pixel electrode; a first common electrode on the first light emitting layer; an auxiliary electrode on the pixel defining layer and in contact with the first common electrode; a first bank on the auxiliary electrode; and a second bank on the first bank and having side surfaces protruding beyond side surfaces of the first bank. A width of a lower surface of the first bank and a width of an upper surface of the first bank are different from each other.

The width of the lower surface of the first bank may be smaller than that of the upper surface of the first bank.

A cross-sectional of the first bank may have a width reducing from the upper surface toward the lower surface.

The auxiliary electrode may include at least one of copper, aluminum, and molybdenum.

In the display device according to embodiments of the present disclosure, permeation of an etchant or moisture into a light emitting element may be avoided. Also, damage to the light emitting element due to an etchant or moisture may be avoided so that a luminance difference between the light emitting elements may be reduced.

The aspects and features of the embodiments of the present disclosure are not limited to those mentioned above and more various aspects and features are included in the following description of the present disclosure.

### BRIEF DESCRIPTION OF THE DRAWINGS

The above and other aspects and features of the present disclosure will become more apparent by describing, in detail, embodiments thereof with reference to the attached drawings, in which:

FIG. 1 is a perspective view illustrating a display device according to one embodiment;

FIG. 2 is a cross-sectional view of the display device shown in FIG. 1;

FIG. 3 is a plan view illustrating an arrangement of a light emitting element, a lower inorganic encapsulation layer, and a second bank of a display device according to one embodiment;

FIG. 4 is a cross-sectional view of a portion of a display device according to one embodiment;

FIG. 5 is an enlarged view illustrating the area A1 in FIG. 4;

FIGS. 6 to 10 are enlarged views illustrating a display device according to other embodiments;

FIG. 11 is a view illustrating a virtual reality device including a display device according to one embodiment;

FIGS. 12 and 13 are views illustrating a head-mounted display device including a display device according to one embodiment; and

FIG. 14 is a cross-sectional view of pixels in the display device shown in FIGS. 11 to 13 according to one embodiment.

### DETAILED DESCRIPTION

The present disclosure will now be described more fully hereinafter with reference to the accompanying drawings, in which embodiments of the present disclosure are shown. The present disclosure may, however, be embodied in different forms and should not be construed as limited to the embodiments set forth herein. Rather, these embodiments are provided so that this disclosure will be thorough and complete and will fully convey the scope of the present disclosure to those skilled in the art.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. For example, the expression “at least one of a, b, or c” indicates only a, only b, only c, both a and b, both a and c, both b and c, all of a, b, and c, or variations thereof. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

Hereinafter, embodiments of the present disclosure will be described with reference to the accompanying drawings.

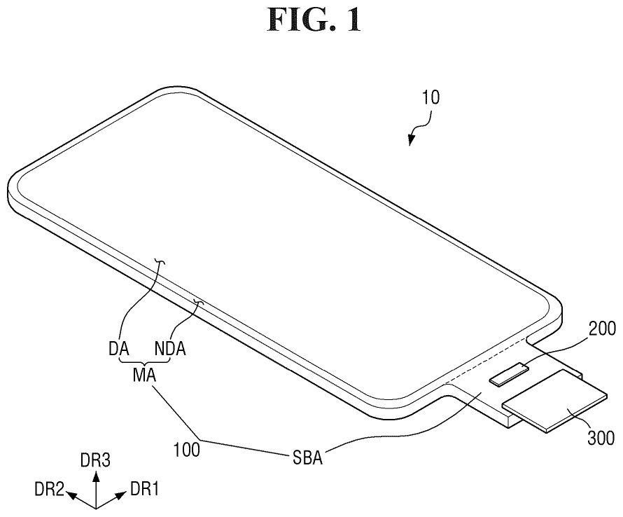

FIG. 1 is a perspective view illustrating a display device according to one embodiment.

Referring to FIG. 1, a display device 10, according to one embodiment, may be included in an electronic device to provide an image displayed on the electronic device. The electronic device may refer to all electronic devices that include (or provide) a display screen. For example, a television, a laptop computer, a monitor, an advertising board, an Internet of Things (IoT) device, a mobile phone, a smart phone, a tablet personal computer (PC), an electronic watch, smart glasses, a smart watch, a watch phone, a head mounted display, a mobile communication terminal, an electronic diary, an electronic book, a portable multimedia player (PMP), a navigator, a game machine, a digital camera, a camcorder, and the like, which provide a display screen, may be included in the electronic device.

Various modifications may be made to the shape of the display device 10. For example, the display device 10 may have a shape similar to a rectangular shape having a short side in a first direction DR1 and a long side in a second direction DR2. A corner at where the short side in the first direction DR1 and the long side in the second direction DR2 meet may be rounded to have a curvature but is not limited thereto and may form a right angle. A planar shape of the display device 10 may be formed to be similar to other polygonal shape, a circular shape, or an oval shape without being limited to the rectangular shape.

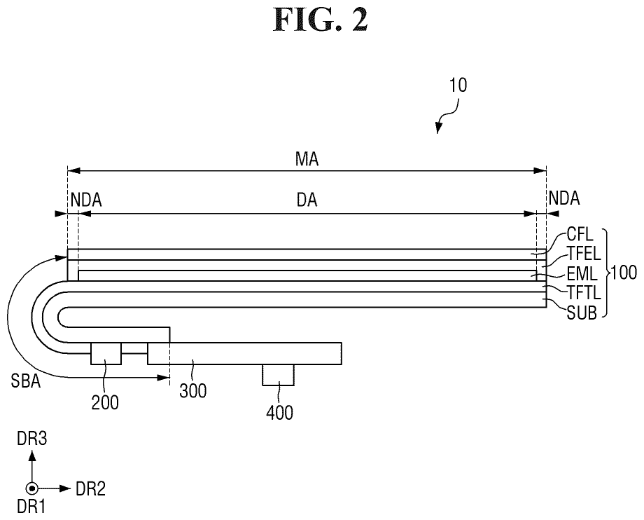

The display device 10 may include a display panel 100, a display driver 200, a circuit board 300, and a touch driver 400 (see, e.g., FIG. 2).

The display panel 100 may have a main area MA and a sub-area SBA.

The main area MA may include a display area DA having pixels for displaying an image and a non-display area NDA disposed near (e.g., adjacent to) the display area DA. The display area DA may emit light from a plurality of light emission areas or a plurality of opening areas. For example, the display panel 100 may include a pixel circuit including switching elements, a pixel defining layer defining a light emission area or an opening area, and a self-light emitting element.

For example, the self-light emitting element may include at least one of an organic light emitting diode including an organic light emitting layer, a quantum dot light emitting diode LED including a quantum dot light emitting layer, an inorganic LED including an inorganic semiconductor, and a micro LED.

A plurality of pixels, a plurality of scan lines, a plurality of data lines, and a plurality of power lines may be disposed in the display area DA. Each of the plurality of pixels may be defined as a minimum unit for emitting light, and each of the above-described self-light emitting elements may be each pixel. The plurality of scan lines may supply a scan signal received from the scan driver to the plurality of pixels. The plurality of data lines may supply a data voltage received from the display driver 200 to the plurality of pixels. The plurality of power lines may supply a power voltage received from the display driver 200 to the plurality of pixels.

The non-display area NDA may be an outer area around the display area DA. The non-display area NDA may be defined as an edge area of the main area MA of the display panel 100. The non-display area NDA may include a scan driver for supplying scan signals to scan lines and fan-out lines for connecting the display driver 200 with the display area DA.

The sub-area SBA may extend from one side of the main area MA. The sub-area SBA may include a flexible material capable of being subjected to bending, folding, rolling, and the like. For example, when the sub-area SBA is bent, the sub-area SBA may overlap the main area MA in a thickness direction (e.g., the third direction DR3). The sub-area SBA may include a display driver 200 and a pad portion connected to the circuit board 300. In another embodiment, the sub-area SBA may be omitted, and the display driver 200 and the pad portion may be disposed in the non-display area NDA.

The display driver 200 may output signals and voltages for driving the display panel 100. The display driver 200 may supply data voltages to the data lines. The display driver 200 may supply the power voltage to the power line and may supply scan control signals to the scan driver. The display driver 200 may be formed of an integrated circuit (IC) and may be packaged on the display panel 100 by a chip on glass (COG) process, a chip on plastic (COP) process, or an ultrasonic bonding process. For example, the display driver 200 may be disposed in the sub-area SBA and may overlap the main area MA in the thickness direction (e.g., the third direction DR3) by bending of the sub-area SBA. For another example, the display driver 200 may be packaged on the circuit board 300.

The circuit board 300 may be attached onto the pad portion of the display panel 100 by using an anisotropic conductive film (ACF). Lead lines of the circuit board 300 may electrically be connected to the pad portion of the display panel 100. The circuit board 300 may be a flexible printed circuit board, a rigid printed circuit board, or a flexible film, such as a chip on film.

FIG. 2 is a cross-sectional view of the display device shown in FIG. 1 viewed at a side. In other words, FIG. 2 relates to a side of the display device shown in FIG. 1 in a folded state.

Referring to FIG. 2, the display panel 100 may include a substrate SUB, a thin film transistor layer TFTL, a light emitting element layer EML, a thin film encapsulation layer TFEL, and a color filter layer CFL.

The substrate SUB may be a base substrate or a base member. The substrate SUB may be a flexible substrate capable of being subjected to bending, folding, rolling, or the like. For example, the substrate SUB may be a silicon substrate, a germanium substrate, or a silicon-germanium substrate but is not limited thereto. In another embodiment, the substrate SUB may include a polymer resin, such as polyimide (PI). In other embodiments, the substrate SUB may include a glass material or a metal material.

The thin film transistor layer TFTL may be disposed on the substrate SUB. The thin film transistor layer TFTL may include a plurality of thin film transistors constituting (or forming) a pixel circuit of pixels. The thin film transistor layer TFTL may further include gate lines, data lines, power lines, scan control lines, fan-out lines for connecting the display driver 200 with the data lines, and lead lines for connecting the display driver 200 with the pad portion. Each of the thin film transistors may include a semiconductor area, a source electrode, a drain electrode, and a gate electrode. For example, when the gate driver is formed at one side of the non-display area NDA of the display panel 100, the gate driver may include thin film transistors.

The thin film transistor layer TFTL may be disposed in the display area DA, the non-display area NDA, and the sub-area SBA. The thin film transistors, the gate lines, the data lines, and the power lines of respective pixels of the thin film transistor layer TFTL may be disposed in the display area DA. The scan control lines and the fan-out lines of the thin film transistor layer TFTL may be disposed in the non-display area NDA. The lead lines of the thin film transistor layer TFTL may be disposed in the sub-area SBA.

The light emitting element layer EML may be disposed on the thin film transistor layer TFTL. The light emitting element layer EML may include a plurality of light emitting elements that include a first electrode, a second electrode, and a light emitting layer configured to emit light, and a pixel defining layer that defines pixels. The plurality of light emitting elements of the light emitting element layer EML may be disposed in the display area DA.

In one embodiment, the light emitting layer may be an organic light emitting layer that includes an organic material. The light emitting layer may include a hole transporting layer, an organic light emitting layer, and an electron transporting layer. When the first electrode receives a voltage through the thin film transistor of the thin film transistor layer TFTL and the second electrode receives a cathode voltage, holes and electrons may move to the organic light emitting layer through the hole transporting layer and the electron transporting layer, respectively, and may be recombined with each other in the organic light emitting layer to emit light.

In another embodiment, the light emitting element may include a quantum dot light emitting diode including a quantum dot light emitting layer, an inorganic light emitting diode including an inorganic semiconductor, or a micro light emitting diode.

The thin film encapsulation layer TFEL may cover an upper surface and side surfaces of the light emitting element layer EML and may protect the light emitting element layer EML. The thin film encapsulation layer TFEL may include at least one inorganic film and at least one organic film to encapsulate the light emitting element layer EML.

The color filter layer CFL may be disposed on the thin film encapsulation layer TFEL. The color filter layer CFL may include a plurality of color filters respectively corresponding to the plurality of light emission areas. Each of the color filters may selectively transmit light of a particular wavelength and may block or absorb light of another wavelength. The color filter layer CFL may absorb a portion of light introduced from (or incident from) the outside of the display device 10 to reduce reflective light due to external light. Therefore, the color filter layer CFL may prevent distortion of a color, which is caused by external light reflection, from occurring.

Because the color filter layer CFL is directly disposed on the thin film encapsulation layer TFEL, the display device 10 may not require a separate substrate for the color filter layer CFL. Therefore, a thickness of the display device 10 may be relatively reduced.

In some embodiments, the display device 10 may further include an optical device. The optical device may emit or receive light of an infrared, ultraviolet, or visible band. For example, the optical device may be an optical sensor for sensing light incident on the display device 10, such as a proximity sensor, an illuminance sensor, a camera sensor, a fingerprint sensor, or an image sensor.

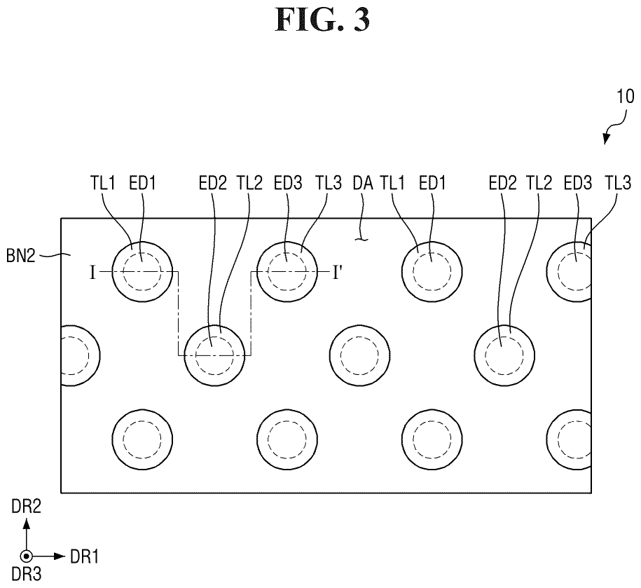

FIG. 3 is a plan view illustrating a portion of a display device according to one embodiment. FIG. 3 is a plan view illustrating arrangement of light emitting elements ED1, ED2, and ED3, lower inorganic encapsulation layers TL1, TL2, and TL3, and a second bank BN2 in a display area DA of a display device 10.

Referring to FIG. 3, the second bank BN2 may expose a portion of the display area DA while covering the display area DA. An opening (illustrated as a dotted area in FIG. 3) is formed in the area exposed without being covered by the second bank BN2, and the light emitting elements ED1, ED2, and ED3 may be disposed in each opening. The lower inorganic encapsulation layers TL1, TL2, and TL3 may cover a boundary portion of the opening on the second bank BN2 and may cover the light emitting elements ED1, ED2, and ED3 in the opening.

Although the area exposed without being covered by the second bank BN2 is shown in FIG. 3 as having a circular shape, it may have a polygonal shape, such as a triangular shape, a quadrangular shape, or a hexagonal shape, and a shape of the lower inorganic encapsulation layers TL1, TL2, and TL3 covering the exposed area and its periphery may be also modified. A portion of the lower inorganic encapsulation layers TL1, TL2, and TL3 may be disposed at a level higher than (or above) that of the second bank BN2, and the light emitting elements ED1, ED2, and ED3 may be disposed at a level lower than (or below) that of the second bank BN2.

The plurality of light emitting elements ED1, ED2, and ED3 may be disposed in a Pentile® type, for example, a diamond Pentile® type or a diamond pixel arrangement. Pentile® is a registered trademark of Samsung Display Co., Ltd. For example, the first light emitting element ED1 and the third light emitting element ED3 may be spaced apart from each other in the first direction DR1 and may be alternately disposed in the first direction DR1 and the second direction DR2. The second light emitting element ED2 may be spaced apart from another adjacent second light emitting element ED2 in the first direction DR1 and the second direction DR2. The second light emitting element ED2 and the first light emitting element ED1 or the second light emitting element ED2 and the third light emitting element ED3 may be alternately disposed along any one direction on a plane defined by the first direction DR1 and the second direction DR2. The shapes and arrangements of the areas exposed without being covered by the second bank BN2 and the plurality of light emitting elements are not limited to the arrangement shown in FIG. 3.

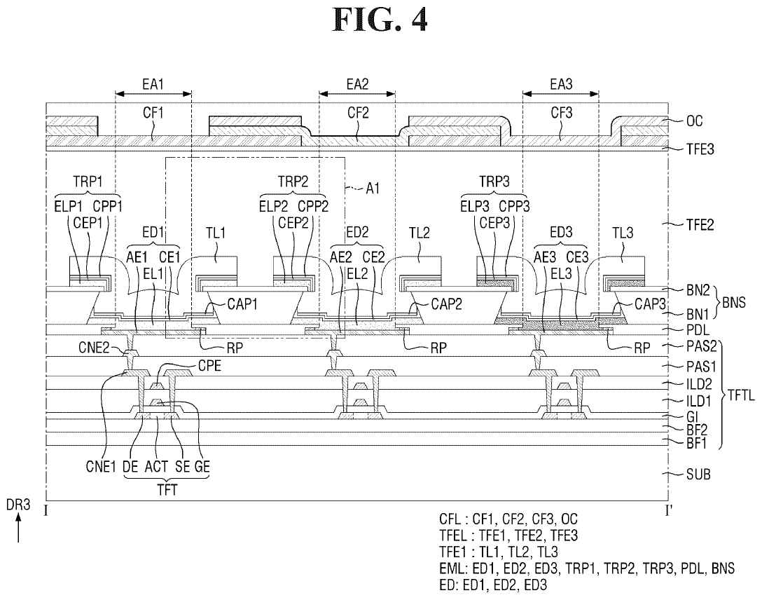

FIG. 4 is a cross-sectional view of a portion of a display device according to one embodiment. In detail, FIG. 4 is a cross-sectional view taken along the line I-I′ in FIG. 3. FIG. 4 illustrates a cross-section of the substrate SUB, the thin film transistor layer TFTL, the light emitting element layer EML, the thin film encapsulation layer TFEL, and the color filter layer CFL.

The thin film transistor layer TFTL may include a first buffer layer BF1, a lower metal layer, a second buffer layer BF2, a thin film transistor TFT, a gate insulating layer GI, a first interlayer insulating layer ILD1, a capacitor electrode CPE, a second interlayer insulating layer ILD2, a first connection electrode CNE1, a first passivation layer PAS1, a second connection electrode CNE2, and a second passivation layer PAS2.

The first buffer layer BF1 may be disposed on the substrate SUB. The first buffer layer BF1 may include an inorganic film for preventing permeation of air or moisture. For example, the first buffer layer BF1 may include a plurality of inorganic films that are alternately stacked on each other.

The lower metal layer may be selectively disposed on the first buffer layer BF1. For example, the lower metal layer may be formed as a single layer or multi-layer made of any one of molybdenum (Mo), aluminum (Al), chromium (Cr), gold (Au), titanium (Ti), nickel (Ni), neodymium (Nd), and copper (Cu), or an alloy thereof.

The second buffer layer BF2 may cover the first buffer layer BF1 and the lower metal layer. The second buffer layer BF2 may include an inorganic film for preventing permeation of air or moisture. For example, the second buffer layer BF2 may include a plurality of inorganic films that are alternately stacked on each other.

The thin film transistor TFT may be disposed on the second buffer layer BF2 and may constitute a pixel circuit of each of the plurality of pixels. For example, the thin film transistor TFT may be a driving transistor or a switching transistor of the pixel circuit. The thin film transistor TFT may include a semiconductor layer ACT, a source electrode SE, a drain electrode DE, and a gate electrode GE.

The semiconductor layer ACT may be disposed on the second buffer layer BF2. The semiconductor layer ACT may overlap the lower metal layer and the gate electrode GE in the third direction DR3 and may be insulated from the gate electrode GE by the gate insulating layer GI. A portion of the semiconductor layer ACT may form the source electrode SE and the drain electrode DE by conductorizing (e.g., may doping to make conductive) a material of the semiconductor layer ACT.

The gate electrode GE may be disposed on the gate insulating layer GI. The gate electrode GE may overlap the semiconductor layer ACT in the third direction DR3 with the gate insulating layer GI interposed therebetween.

The gate insulating layer GI may be disposed on the semiconductor layer ACT. For example, the gate insulating layer GI may cover the semiconductor layer ACT and the second buffer layer BF2 and may insulate the semiconductor layer ACT from the gate electrode GE. The gate insulating layer GI may include a contact hole (e.g., a contact opening) through which the first connection electrode CNE1 passes.

The first interlayer insulating layer ILD1 may cover the gate electrode GE and the gate insulating layer GI. The first interlayer insulating layer ILD1 may include a contact hole (e.g., a contact opening) through which the first connection electrode CNE1 passes. The contact hole in the first interlayer insulating layer ILD1 may be connected to (e.g., may be open to) the contact hole in the gate insulating layer GI and a contact hole (e.g., a contact opening) in the second interlayer insulating layer ILD2.

The capacitor electrode CPE may be disposed on the first interlayer insulating layer ILD1. The capacitor electrode CPE may overlap the gate electrode GE in the third direction DR3. The capacitor electrode CPE and the gate electrode GE may form a capacitance therebetween.

The second interlayer insulating layer ILD2 may cover the capacitor electrode CPE and the first interlayer insulating layer ILD1. The second interlayer insulating layer ILD2 may have a contact hole (e.g., a contact opening) through which the first connection electrode CNE1 passes. The contact hole in the second interlayer insulating layer ILD2 may be connected to (e.g., may be open to) the contact hole in the first interlayer insulating layer ILD1 and the contact hole in the gate insulating layer GI.

The first connection electrode CNE1 may be disposed on the second interlayer insulating layer ILD2. The first connection electrode CNE1 may electrically connect the drain electrode DE of the thin film transistor TFT with the second connection electrode CNE2. The first connection electrode CNE1 may be inserted into (or may be formed in) the contact holes formed in the second interlayer insulating layer ILD2, the first interlayer insulating layer ILD1, and the gate insulating layer GI to contact the drain electrode DE of the thin film transistor TFT.

The first passivation layer PAS1 may cover the first connection electrode CNE1 and the second interlayer insulating layer ILD2. The first passivation layer PAS1 may protect the thin film transistor TFT. The first passivation layer PAS1 may have a contact hole (e.g., a contact opening) through which the second connection electrode CNE2 passes.

The second connection electrode CNE2 may be disposed on the first passivation layer PAS1. The second connection electrode CNE2 may electrically connect the first connection electrode CNE1 with pixel electrodes AE1, AE2, and AE3 of the light emitting element ED. The second connection electrode CNE2 may be inserted into the contact hole formed in the first passivation layer PAS1 to contact the first connection electrode CNE1.

The second passivation layer PAS2 may cover the second connection electrode CNE2 and the first passivation layer PAS1. The second passivation layer PAS2 may have a contact hole (e.g., a contact opening) through which the pixel electrode AE1, AE2, and AE3 of the light emitting element ED pass.

The light emitting element layer EML may be disposed on the thin film transistor layer TFTL. The light emitting element layer EML may include a light emitting element ED, a pixel defining layer PDL, capping layers CAP1, CAP2, and CAP3, and a bank structure BNS. The light emitting element ED may include pixel electrodes AE1, AE2, and AE3, light emitting layers EL1, EL2, and EL3, and common electrodes CE1, CE2, and CE3.

The display device 10 may have a plurality of light emission areas EA1, EA2, and EA3 disposed in the display area DA. The light emission areas EA1, EA2, and EA3 may be areas at where light is emitted from the light emitting elements ED1, ED2, and ED3 to pass through the color filter layer CFL in the third direction DR3, and the pixel electrodes AE1, AE2, and AE3, the light emitting layers EL1, EL2, and EL3, and the common electrodes CE1, CE2, and CE3 are sequentially stacked on each other in the light emitting elements ED1, ED2, and ED3, respectively. The light emission areas EA1, EA2, and EA3 may include a first light emission area EA1, a second light emission area EA2, and a third light emission area EA3, which are spaced apart from one another and emit light of the same color or different colors.

In one embodiment, areas or sizes of the first to third light emission areas EA1, EA2, and EA3 may be the same as one another. For example, in the display device 10 illustrated in FIG. 4, the first light emission area EA1, the second light emission area EA2, and the third light emission area EA3 may have the same size but are not limited thereto. In the display device 10, the first to third light emission areas EA1, EA2, and EA3 may have different areas or sizes. For example, the size of the second light emission area EA2 may be larger than that of each of the first light emission area EA1 and the third light emission area EA3, and the size of the third light emission area EA3 may be larger than that of the first light emission area EA1. The intensity of light emitted from the corresponding light emission areas EA1, EA2, and EA3 may vary depending on the sizes of the light emission areas EA1, EA2, and EA3, and the sizes of the light emission areas EA1, EA2, and EA3 may be adjusted so that a color of a screen displayed on the display device 10 may be controlled. In the embodiment shown in FIG. 4, the sizes of the light emission areas EA1, EA2, and EA3 are illustrated as being the same as one another, but the present disclosure is not limited thereto.

In the display device 10, one first light emission area EA1, one second light emission area EA2, and one third light emission area EA3, which are disposed to be adjacent to one another, may form one pixel group. One pixel group may include the light emission areas EA1, EA2, and EA3 that emit light of different colors, thereby representing a white gray scale (e.g., thereby emitting or configured to emit a white color light), but the present disclosure is not limited thereto. A combination of the light emission areas EA1, EA2, and EA3 constituting one pixel group may be variously modified depending on the arrangement of the light emission areas EA1, EA2, and EA3 and the colors of the light emitted from the light emission areas EA1, EA2, and EA3.

The plurality of openings formed in the bank structure BNS of the light emitting element layer EML are defined along a boundary of the bank structure BNS. The first bank BN1 and the second bank BN2 of the bank structure BNS may surround (e.g., may extend around a periphery of) the light emission areas EA1, EA2, and EA3. Each of the openings may include (or may form) one of the first to third light emission areas EA1, EA2 and EA3.

The display device 10 may include a plurality of light emitting elements ED1, ED2, and ED3 respectively disposed in different light emission areas EA1, EA2, and EA3. The light emitting elements ED1, ED2, and ED3 may include a first light emitting element ED1 disposed in the first light emission area EA1, a second light emitting element ED2 disposed in the second light emission area EA2, and a third light emitting element ED3 disposed in the third light emission area EA3.

Each of the light emitting elements ED1, ED2, and ED3 may include pixel electrodes AE1, AE2, and AE3, light emitting layers EL1, EL2, and EL3, and common electrodes CE1, CE2, and CE3, and the light emitting elements ED1, ED2, and ED3 respectively disposed in the different light emission areas EA1, EA2, and EA3 may emit light of different colors depending on materials of the light emitting layers EL1, EL2, and EL3. For example, the first light emitting element ED1 disposed in the first light emission area EA1 may emit first light of a red color, which has a peak wavelength in a range of about 610 nm to about 650 nm, the second light emitting element ED2 disposed in the second light emission area EA2 may emit second light of a green color, which has a peak wavelength in a range of about 510 nm to about 550 nm, and the third light emitting element ED3 disposed in the third light emission area EA3 may emit third light of a blue color, which has a peak wavelength in a range of about 440 nm to about 480 nm. The first to third light emission areas EA1, EA2, and EA3 constituting one pixel may include the light emitting elements ED1, ED2, and ED3 for emitting light of different colors to represent a white gray scale.

In another embodiment, the light emitting layers EL1, EL2, and EL3 may include two or more materials for emitting light of different colors such that one light emitting layer may emit mixture light (e.g., mixed color light). For example, the light emitting layers EL1, EL2, and EL3 may include a material for emitting red light and a material for emitting green light together to emit yellow light or may include all of a material for emitting red light, a material for emitting green light, and a material for emitting blue light to emit white light. The light emitting layers EL1, EL2, and EL3 may have a tandem structure in which a plurality of light emitting stacks are stacked on each other. For example, the light emitting layers EL1, EL2, and EL3 may emit white light by stacking a first stack including a material for emitting red light, a second stack including a material for emitting green light, and a third stack including a material for emitting blue light. In another embodiment, the light emitting layers EL1, EL2, and EL3 may include a third stack including a material for emitting blue light and a fourth stack including a material for emitting yellow light to emit white light.

The pixel electrodes AE1, AE2, and AE3 may be disposed on the second passivation layer PAS2. The pixel electrodes AE1, AE2, and AE3 may be disposed in the plurality of light emission areas EA1, EA2, and EA3, respectively. The pixel electrodes AE1, AE2, and AE3 may include a first pixel electrode AE1 disposed in the first light emission area EA1, a second pixel electrode AE2 disposed in the second light emission area EA2, and a third pixel electrode AE3 disposed in the third light emission area EA3. The first pixel electrode AE1, the second pixel electrode AE2, and the third pixel electrode AE3 may be spaced apart from one another on the second passivation layer PAS2.

The pixel electrodes AE1, AE2, and AE3 may be electrically connected to the drain electrode DE of the thin film transistor TFT through the first and second connection electrodes CNE1 and CNE2. Edges of the spaced pixel electrodes AE1, AE2, and AE3 may be covered by the pixel defining layer PDL so that the first to third pixel electrodes AE1, AE2, and AE3 may be insulated from one another.

The pixel electrodes AE1, AE2, and AE3 may include a transparent electrode material and/or a conductive metal material. The metal material may be one or more of silver (Ag), copper (Cu), aluminum (Al), nickel (Ni), lanthanum (La), titanium (Ti). The pixel electrodes AE1, AE2, and AE3 may also include titanium nitride (TiN). The transparent electrode material may be one or more of Indium Tin Oxide (ITO), Indium Zinc Oxide (IZO), and Indium Tin Zinc Oxide (ITZO). The pixel electrodes AE1, AE2, and AE3 may have a multi-layered structure of a transparent electrode material and a conductive metal material.

The pixel defining layer PDL may be disposed on the second passivation layer PAS2, a residual pattern RP, and the pixel electrodes AE1, AE2, and AE3. The pixel defining layer PDL may be entirely disposed on the second passivation layer PAS2 and may cover side surfaces of the pixel electrodes AE1, AE2, and AE3 and the residual pattern RP while exposing a portion of upper surfaces of the pixel electrodes AE1, AE2, and AE3. For example, the pixel defining layer PDL may expose the first pixel electrode AE1 in the first light emission area EA1, and the first light emitting layer EL1 may be disposed directly on the first pixel electrode AE1.

The pixel defining layer PDL may include an inorganic insulating material. The pixel defining layer PDL may include at least one of a silicon nitride layer, a silicon oxynitride layer, a silicon oxide layer, a titanium oxide layer, an aluminum oxide layer, a tantalum oxide layer, a hafnium oxide layer, a zinc oxide layer, or an amorphous silicon layer.

According to one embodiment, the pixel defining layer PDL is disposed on the pixel electrodes AE1, AE2, and AE3 and may be spaced apart from the upper surfaces of the pixel electrodes AE1, AE2, and AE3. The pixel defining layer PDL may not directly contact the upper surfaces of the pixel electrodes AE1, AE2, and AE3 but may partially overlap the upper surfaces of the pixel electrodes AE1, AE2, and AE3 in the thickness direction (for example, the third direction DR3) of the substrate SUB, and the residual pattern RP may be disposed between the pixel defining layer PDL and the pixel electrodes AE1, AE2, and AE3. However, the pixel defining layer PDL may direly contact the side surfaces of the pixel electrode AE1, AE2, and AE3. Side surfaces of the pixel defining layer PDL may be more protruded toward the light emission areas EA1, EA2, and EA3 than side surfaces of the second bank BN2 (e.g., side surfaces of the pixel defining layer PDL may protrude beyond the side surfaces of the second bank BN2 toward the light emission areas EA1, EA2, and EA3).

The residual pattern RP may be disposed on the edge of each of the pixel electrodes AE1, AE2, and AE3. The pixel defining layer PDL may not directly contact the upper surfaces of the pixel electrodes AE1, AE2, and AE3 due to the residual pattern RP. In a manufacturing process of the display device 10, a portion of a sacrificial layer disposed on the pixel electrodes AE1, AE2, and AE3 may be removed so that the residual pattern RP may be formed. The residual pattern RP may include a metal or an oxide semiconductor material. In the illustrated embodiment, side surfaces of the residual pattern RP, which are directed toward the light emission areas EA1, EA2, and EA3, are illustrated as being more recessed than the side surfaces of the pixel defining layer PDL, but the present disclosure is not limited thereto. The side surfaces of the residual pattern RP may be aligned with the side surfaces of the pixel defining layer PDL toward the light emission areas EA1, EA2, and EA3, or may be more protruded than the side surfaces of the pixel defining layer PDL. The side surfaces of the pixel defining layer PDL may be the outermost side surfaces directed toward the light emission areas EA1, EA2, and EA3.

The light emitting layers EL1, EL2, and EL3 may be disposed on the pixel electrodes AE1, AE2, and AE3. The light emitting layers EL1, EL2, and EL3 may be organic light emitting layers made of an organic material and may be formed on the pixel electrodes AE1, AE2, and AE3 through a deposition process. The light emitting layers EL1, EL2, and EL3 may have a multi-layered structure, and each of a hole injection material, a hole transporting material, a light emitting material, an electron transporting material, and/or an electron injection material may constitute a layer of the light emitting layers EL1, EL2, and EL3. When the thin film transistor TFT applies a voltage (e.g., a predetermined voltage) to the pixel electrodes AE1, AE2, and AE3 of the light emitting elements ED1, ED2, and ED3 and the common electrodes CE1, CE2, and CE3 of the light emitting elements ED1, ED2, and ED3 receive a common voltage or a cathode voltage, holes and electrons may be injected and transported, and the holes and electrons may be recombined with each other in the light emitting layers EL1, EL2, and EL3 to emit light.

The light emitting layers EL1, EL2, and EL3 may include a first light emitting layer EL1, a second light emitting layer EL2, and a third light emitting layer EL3, which are disposed in the different light emission areas EA1, EA2, and EA3, respectively. The first light emitting layer EL1 may be disposed on the first pixel electrode AE1 in the first light emission area EA1, the second light emitting layer EL2 may be disposed on the second pixel electrode AE2 in the second light emission area EA2, and the third light emitting layer EL3 may be disposed on the third pixel electrode AE3 in the third light emission area EA3. The plurality of light emitting layers EL1, EL2, and EL3 may emit light of different colors, respectively, or one of the light emitting layers EL1, EL2, and EL3 may emit mixture light (e.g., a mixture of light colors). In one embodiment, the first light emitting layer EL1 may emit red light, the second light emitting layer EL2 may emit green light, and the third light emitting layer EL3 may emit blue light. In another embodiment, the first light emitting layer EL1 may emit yellow light, which is mixture light of red light and green light, and the second light emitting layer EL2 may emit blue light. In another embodiment, the first light emitting layer EL1 may emit white light, which is mixture light of red light, green light, and blue light. The light emitting layer for emitting mixture light or white light may have a tandem structure in which a plurality of light emitting stacks are stacked.

The light emitting layers EL1, EL2, and EL3 may be disposed on an upper surface of the pixel defining layer PDL. In one embodiment, the light emitting layers EL1, EL2, and EL3 may be disposed in spaces between the pixel electrodes AE1, AE2, and AE3 and the pixel defining layer PDL. In one embodiment, the light emitting layers EL1, EL2, and EL3 may be in contact with the pixel defining layer PDL, the residual pattern RP, and the pixel electrodes AE1, AE2, and AE3.

The common electrodes CE1, CE2, and CE3 may be disposed on the light emitting layers EL1, EL2, and EL3. The common electrodes CE1, CE2, and CE3 may include a transparent conductive material so that light generated from the light emitting layers EL1, EL2, and EL3 may be emitted. The common electrodes CE1, CE2, and CE3 may receive a common voltage or a low potential voltage. When the pixel electrodes AE1, AE2, and AE3 receive a voltage corresponding to the data voltage and the common electrodes CE1, CE2, and CE3 receive a low potential voltage, a potential difference may be formed between the pixel electrodes AE1, AE2, and AE3 and the common electrodes CE1, CE2, and CE3 such that the light emitting layers EL1, EL2 and EL3 may emit light.

The common electrodes CE1, CE2, and CE3 may include a first common electrode CE1, a second common electrode CE2, and a third common electrode CE3, which are disposed in the different light emission areas EA1, EA2, and EA3, respectively. The first common electrode CE1 may be disposed on the first light emitting layer EL1 in the first light emission area EA1, the second common electrode CE2 may be disposed on the second light emitting layer EL2 in the second light emission area EA2, and the third common electrode CE3 may be disposed on the third light emitting layer EL3 in the third light emission area EA3. The first to third common electrodes CE1, CE2, and CE3 may be spaced apart from one another.

Capping layers CAP1, CAP2, and CAP3 may be disposed on the common electrodes CE1, CE2, and CE3, respectively. The capping layers CAP1, CAP2, and CAP3 may include an organic material or an inorganic insulating material to cover the light emitting elements ED1, ED2, and ED3. The capping layers CAP1, CAP2, and CAP3 may prevent the light emitting elements ED1, ED2, and ED3 from being damaged by external air. In an embodiment, the capping layers CAP1, CAP2, and CAP3 may include an organic material, such as a-NPD, NPB, TPD, m-MTDATA, Alq₃, LiF, and/or CuPc, or an inorganic material, such as aluminum oxide, titanium oxide, tantalum oxide, hafnium oxide, zinc oxide, silicon oxide, silicon nitride, and/or silicon oxynitride.

The capping layers CAP1, CAP2, and CAP3 may include a first capping layer CAP1, a second capping layer CAP2, and a third capping layer CAP3, which are disposed in the different light emission areas EA1, EA2, and EA3, respectively. The first to third capping layers CAP1, CAP2, and CAP3 may be spaced apart from one another.

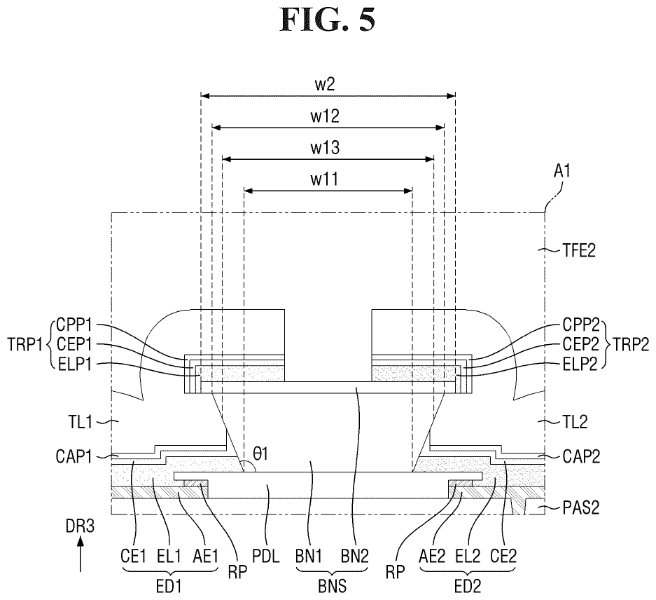

FIG. 5 is an enlarged view of a bank structure BNS and is an enlarged view of the area A1 in FIG. 4. Although FIG. 5 illustrates the bank structure BNS disposed between the first light emission area EA1 and the second light emission area EA2, the description referencing FIG. 5 may be equally applied to the bank structure BNS between the second light emission area EA2 and the third light emission area EA3 and the bank structure BNS between the third light emission area EA3 and the first light emission area EA1.

The display device 10 may include a plurality of bank structures BNS disposed on the pixel defining layer PDL. The bank structure BNS may have a structure in which banks BN1 and BN2 including their respective materials different from each other are sequentially stacked, may have a plurality of openings including (e.g., forming or overlapping) light emission areas EA1, EA2 and EA3, and may be disposed to overlap a light blocking layer, which will be described later. The light emitting elements ED1, ED2, and ED3 of the display device 10 may be disposed to overlap the openings in the bank structure BNS.

The first bank BN1 may be disposed on the pixel defining layer PDL. The first bank BN1 may have a lower surface facing the pixel defining layer PDL and an upper surface facing the second bank BN2.

Areas (e.g., surface areas) of the lower surface and the upper surface of the first bank BN1 may be different from each other. For example, a width w11 of the lower surface and a width w12 of the upper surface of the first bank BN1 may be different from each other. Herein, a width may be a length measured in a direction parallel with (or parallel to) the substrate SUB (e.g., to an upper surface of the substrate SUB). The first bank BN1 may have a trapezoidal cross-section. The first bank BN1 may have a tapered or reverse-tapered cross-section. The tapered shape refers to a shape having an angle between a lower surface (e.g., the bottom surface) and a side in a cross-sectional view of the first bank BN1, taken along the thickness direction (for example, the third direction DR3) of the substrate, that is smaller than 90°. In addition, the reverse-tapered shape refers to a shape having an angle between the lower surface (e.g., the bottom surface) and the side in the cross-sectional view of the first bank BN1, taken along the thickness direction (for example, the third direction DR3) of the substrate, that is greater than 90°.

In one embodiment, the width w11 of the lower surface of the first bank BN1 may be smaller than the width w12 of the upper surface. An angle 61 between the lower surface and the side of the first bank BN1 may be an obtuse angle greater than 90°. The first bank BN1 may have a reverse-tapered cross-sectional shape having a width reducing (or narrowing) from the upper surface toward the lower surface. The first bank BN1 may have a third width w13 between the upper surface and the lower surface, and the third width w13 may be a numerical value between the width w11 of the lower surface and the width w12 of the upper surface. When the width w11 of the lower surface of the first bank BN1 is smaller than the width w12 of the upper surface, a deposition material of the light emitting layers EL1, EL2, and EL3 and the common electrodes CE1, CE2, and CE3 may be smoothly separated.

The side surfaces of the first bank BN1 may be more recessed than those of the pixel defining layer PDL in an opposite direction of a direction directed toward (e.g., in the direction away from) the light emission areas EA1, EA2 and EA3. The width w11 of the lower surface of the first bank BN1 may be smaller than a width of the upper surface of the pixel defining layer PDL. The side surfaces of the first bank BN1 may be more recessed than those of the second bank BN2 in the opposite direction of the direction directed toward (e.g., in the direction away from) the light emission areas EA1, EA2, and EA3.

The first bank BN1 may include a conductive material. In one embodiment, the first bank BN1 may include a conductive material that does not include a metal. In an embodiment, the first bank BN1 may include one or more of polysilicon, amorphous carbon, graphite, and graphene. The graphite and the graphene may include amorphous carbon between hexagonal crystals of carbon. When the first bank BN1 includes a non-metal conductive material, any concern of high resistance due to a metal oxide is mitigated, and moisture permeation may be avoided due to high adhesion between the first bank BN1 and the lower inorganic encapsulation layers TL1, TL2, and TL3.

In one embodiment, a thickness or height of the first bank BN1 may be in a range of about 3000 Å to about 7000 Å. When the first bank BN1 is within this range, the deposition material of the light emitting layers EL1, EL2, and EL3 and the common electrodes CE1, CE2, and CE3 may be broken (or separated) at a boundary of the openings in the bank structure BNS. In one embodiment, the thickness of the first bank BN1 may be substantially greater than that of the second bank BN2.

The first bank BN1 may expose the common electrodes CE1, CE2, and CE3. According to one embodiment, the common electrodes CE1, CE2, and CE3 may be directly in contact with the first bank BN1. One end and the other end (e.g., the opposite end) of the common electrodes CE1, CE2, and CE3 may be in contact with the side surfaces of the first bank BN1. The common electrodes CE1, CE2, and CE3 of the different light emitting elements ED1, ED2, and ED3 may be directly in contact with the first bank BN1, and the first bank BN1 may include a conductive material so that the common electrodes CE1, CE2, and CE3 may be electrically connected to one another through the first bank BN1.

The light emitting layers EL1, EL2, and EL3 may be directly in contact with the side surfaces of the first bank BN1. An area at where the common electrodes CE1, CE2, and CE3 are in contact with the side surfaces of the first bank BN1 may be greater than an area at where the light emitting layers EL1, EL2, and EL3 are in contact with the side surfaces of the first bank BN1. The common electrodes CE1, CE2, and CE3 may be disposed on the side surfaces of the first bank BN1 to reach an area larger than the light emitting layers EL1, EL2, and EL3 or a higher position on the side surfaces of the first bank BN1. Because the common electrodes CE1, CE2, and CE3 of the different light emitting elements ED1, ED2, and ED3 are electrically connected to one another through the first bank BN1, the common electrodes CE1, CE2 and CE3 may be in contact with the first bank BN1 in more areas to provide various advantages.

The second bank BN2 may be disposed on the first bank BN1. The second bank BN2 may have a tip, that is, an area more protruded than (e.g., protruding beyond) the first bank BN1. The side surfaces of the second bank BN2 may be more protruded toward the light emission areas EA1, EA2, and EA3 than the side surfaces of the first bank BN1. For example, a width w2 of the second bank BN2 may be greater than the width w12 of the upper surface of the first bank BN1. Although the second bank BN2 is illustrated as having a constant width, the second bank BN2 may have different widths at an upper surface and a lower surface. In such an embodiment, the width of the lower surface of the second bank BN2 may be greater than the width w12 of the upper surface of the first bank BN1.

Because the side surfaces of the second bank BN2 have a shape more protruded toward the light emission areas EA1, EA2, and EA3 than the side surfaces of the first bank BN1, the first bank BN1 may form an undercut structure below the tip of the second bank BN2.

In the display device 10, according to one embodiment, the bank structure BNS may have a tip protruded toward the light emission areas EA1, EA2, and EA3 so that the light emitting layers EL1, EL2, and EL3 and the common electrodes CE1, CE2, and CE3, which are spaced apart from each other, may be formed by deposition and etching processes without using a mask. Also, different layers may be individually formed in the different light emission areas EA1, EA2, and EA3 by the deposition process. For example, although the light emitting layers EL1, EL2, and EL3 of the light emitting elements ED1, ED2, and ED3 and the common electrodes CE1, CE2, and CE3 are formed by the deposition process without using a mask, deposited materials may be disconnected by the bank structure BNS interposed therebetween by the tip of the second bank BN2 without being connected from among (e.g., without being connected through) the light emission areas EA1, EA2, and EA3. After a material for forming a specific layer is formed on an entire surface of the display device 10, different layers may be individually formed in the different light emission areas EA1, EA2, and EA3 through a process of removing a layer formed in an undesired area through etching. The different light emitting elements ED1, ED2, and ED3 may be respectively formed in the light emission areas EA1, EA2, and EA3 through deposition and etching processes without using a mask process, and accordingly, unnecessary elements in the display device 10 may be omitted and a size of the non-display area NDA may be reduced or minimized.

A side shape of the bank structure BNS may have a structure formed due to a difference in etch rates in an etching process because the first bank BN1 and the second bank BN2 include respective materials that are different from each other. According to one embodiment, the second bank BN2 may include a material having an etch rate slower than that of the first bank BN1 such that the first bank BN1 may be further etched during the etching process so that the lower surface of the tip of the second bank BN2 may be exposed and an undercut may be formed below the second bank BN2.

The second bank BN2 may include a silicon inorganic material such as silicon oxide, silicon nitride and/or silicon oxynitride, or may include a metal. In one embodiment, the second bank BN2 may include one or more of SiOₓ, SiN_{y}, SiOₓN_{y}, and a metal. An example of the metal included in the second bank BN2 may be titanium (Ti) or molybdenum (Mo) but is not limited thereto. In one embodiment, the second bank BN2 may have a single-layered structure or multi-layered structure of the aforementioned materials.

The tip of the second bank BN2 may overlap the common electrodes CE1, CE2, and CE3, the light emitting layers EL1, EL2, and EL3, and/or the pixel defining layer PDL in the third direction DR3 perpendicular to the substrate SUB. The common electrodes CE1, CE2, and CE3 may be spaced apart from one another, and one end and the other end (e.g., the opposite end) of each of the common electrodes CE1, CE2, and CE3 may overlap the second bank BN2 in the thickness direction (for example, the third direction DR3) of the substrate SUB. A maximum vertical distance from the substrate SUB to the common electrodes CE1, CE2, and CE3 may be shorter than a maximum vertical distance from the substrate SUB to the upper surface of the first bank BN1.

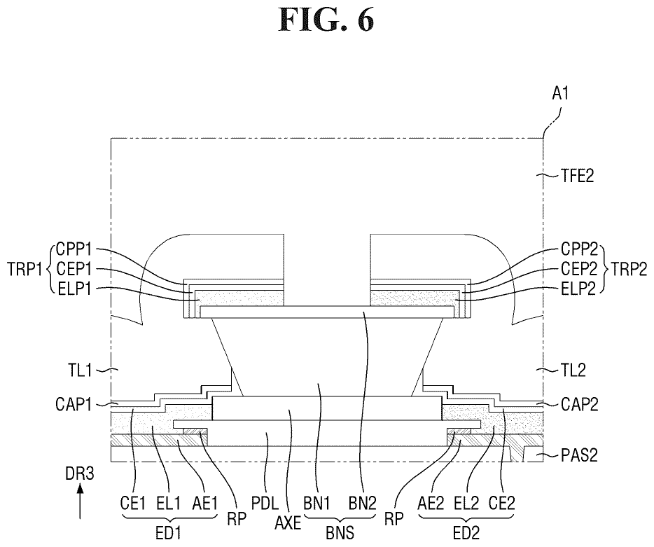

FIG. 6 is an enlarged view illustrating a bank structure BNS of a display device according to another embodiment. The embodiment shown in FIG. 6 differs from the embodiment shown in FIG. 5 in that an auxiliary electrode AXE is disposed between the first bank BN1 and the pixel defining layer PDL. The above description may be applied to the other elements in addition to the auxiliary electrode AXE, and the auxiliary electrode AXE will be described in detail.

The auxiliary electrode AXE may be in contact with the common electrodes CE1, CE2, and CE3, and may include a conductive material. The common electrodes CE1, CE2, and CE3 may be electrically connected to one another through the auxiliary electrode AXE as well as the first bank BN1. The auxiliary electrode AXE may include a low resistance metal. In one embodiment, the auxiliary electrode AXE may include one or more of copper, aluminum, and molybdenum.

In one embodiment, the light emitting layers EL1, EL2, and EL3 may be directly in contact with the auxiliary electrode AXE and may not be in contact with the first bank BN1. An area of the common electrodes CE1, CE2, and CE3 that are in contact with the first bank BN1 and the auxiliary electrode AXE may be larger than an area of the light emitting layers EL1, EL2, and EL3 that are in contact with the auxiliary electrode AXE.

A width of the auxiliary electrode AXE may be different from the width of the lower surface of the first bank BN1. In one embodiment, the width of the auxiliary electrode AXE may be greater than the width of the lower surface of the first bank BN1. The width of the auxiliary electrode AXE may be smaller than the width of the upper surface of the pixel defining layer PDL.

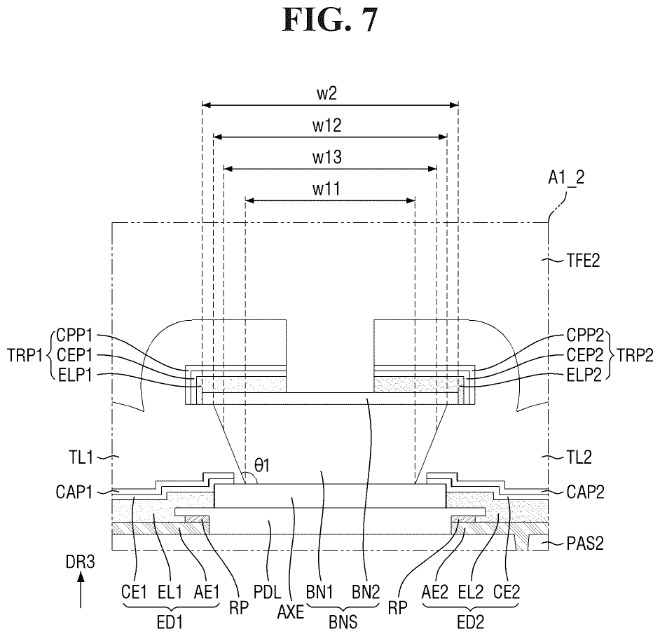

FIG. 7 is an enlarged view illustrating a display device according to another embodiment. The embodiment shown in FIG. 7 differs from that shown in FIG. 6 in that the common electrodes CE1, CE2, and CE3 are not in contact with the first bank BN1 and ends of the common electrodes CE1, CE2, and CE3 are spaced apart from the side surfaces of the first bank BN1.

When the common electrodes CE1, CE2, and CE3 are disconnected from the first bank BN1 without being electrically connected to the first bank BN1 or the common electrodes CE1, CE2, and CE3 are not formed on the side surfaces of the first bank BN1, the common electrodes CE1, CE2, and CE3 spaced apart from one another may be electrically connected to one another through the auxiliary electrode AXE. The common electrodes CE1, CE2, and CE3 may be in contact with an upper surface and side surfaces of the auxiliary electrode AXE.

The light emitting layers EL1, EL2, and EL3 may be directly in contact with the auxiliary electrode AXE. An area at where the common electrodes CE1, CE2, and CE3 are in contact with the auxiliary electrode AXE may be larger than an area at where the light emitting layers EL1, EL2, and EL3 are in contact with the auxiliary electrode AXE.

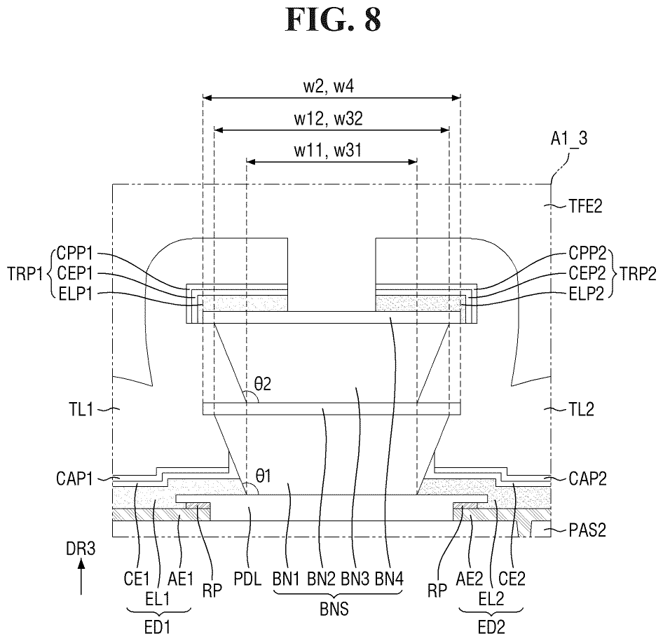

FIG. 8 is an enlarged view illustrating a bank structure BNS of a display device according to another embodiment. The embodiment shown in FIG. 8 differs from that shown in FIG. 5 in that a third bank BN3 and a fourth bank BN4 are stacked on the second bank BN2.

The third bank BN3 may be disposed on the second bank BN2. The third bank BN3 may have a lower surface facing the second bank BN2 and an upper surface opposite to the lower surface.

Areas (e.g., surface areas) of the lower surface and the upper surface of the third bank BN3 may be different from each other. A width w31 of the lower surface of the third bank BN3 and a width w32 of the upper surface of the third bank BN3 may be different from each other. The third bank BN3 may have a trapezoidal cross-sectional shape. The third bank BN3 may have a tapered or reverse-tapered cross-sectional shape.

In one embodiment, the width w31 of the lower surface of the third bank BN3 may be smaller than the width w32 of the upper surface of the third bank BN3. The width w31 of the lower surface of the third bank BN3 may be smaller than the width w2 of the second bank BN2.

FIG. 8 illustrates an embodiment in which the width w31 of the lower surface of the third bank BN3 is the same as the width w11 of the lower surface of the first bank BN1, but the present disclosure is not limited thereto. The width w31 of the lower surface of the third bank BN3 may be different from the width w11 of the lower surface of the first bank BN1. The width w31 of the lower surface of the third bank BN3 may be greater than or smaller than the width w11 of the lower surface of the first bank BN1. Although the width w32 of the upper surface of the third bank BN3 is illustrated as being the same as the width w12 of the upper surface of the first bank BN1 in FIG. 8, the present disclosure is not limited thereto. The width w32 of the upper surface of the third bank BN3 may be different from the width w12 of the upper surface of the first bank BN1. The width w32 of an upper surface of the third bank BN3 may be greater than or smaller than the width w12 of the upper surface of the first bank BN1.

An angle θ2 between the lower surface and the side of the third bank BN3 may be an obtuse angle greater than 90°. The angle θ2 between the lower surface and the side of the third bank BN3 may be the same as or different from the angle θ1 defined between the lower surface and the side of the first bank BN1. The angle θ2 between the lower surface and the side of the third bank BN3 may be greater than or smaller than the angle θ1 between the lower surface and the side of the first bank BN1.

A thickness of the third bank BN3 may be greater than a thickness of the fourth bank BN4. The thickness of the third bank BN3 may be the same as or different from the thickness of the first bank BN1.

The third bank BN3 may include a conductive material. In one embodiment, the third bank BN3 may include a conductive material that does not include a metal. In an embodiment, the third bank BN3 may include one or more of polysilicon, amorphous carbon, graphite, and graphene. In one embodiment, the third bank BN3 may include the same material as that of the first bank BN1.

The fourth bank BN4 may be disposed on the third bank BN3. Side surfaces of the fourth bank BN4 may be more protruded toward the light emission areas EA1, EA2, and EA3 than the side surfaces of the third bank BN3. A width w4 of the fourth bank BN4 may be greater than the width w32 of the upper surface of the third bank BN3. Although the fourth bank BN4 is illustrated as having a constant width in FIG. 8, the fourth bank BN4 may have a difference in width between the upper surface and the lower surface. The width of the lower surface of the fourth bank BN4 may be greater than the width w32 of the upper surface of the third bank BN3.

The fourth bank BN4 may include a material different from that of the third bank BN3. The fourth bank BN4 may include a silicon inorganic material, such as silicon oxide, silicon nitride, and/or silicon oxynitride, or may include a metal. In one embodiment, the fourth bank BN4 may include one or more of SiOₓ, SiN_{y}, SiOₓN_{y}, and a metal. An example of the metal included in the fourth bank BN4 may be titanium (Ti) or molybdenum (Mo) but is not limited thereto. In one embodiment, the fourth bank BN4 may include the same material as that of the second bank BN2.

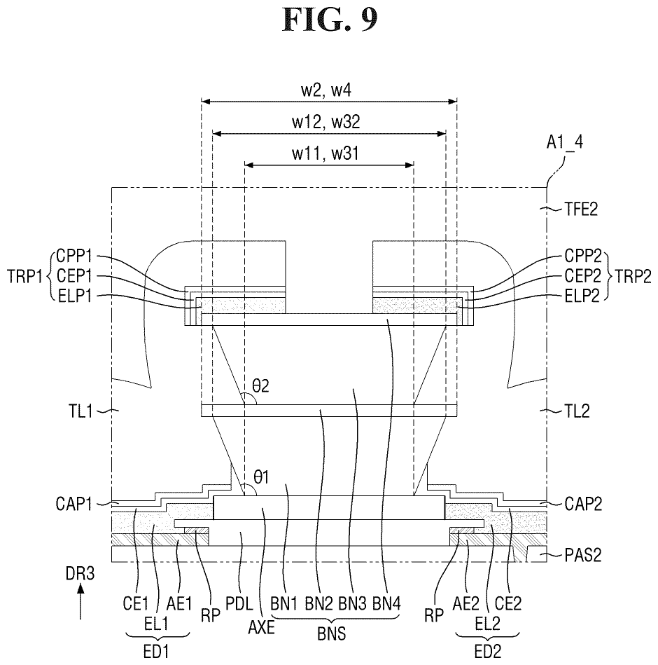

FIG. 9 is an enlarged view illustrating a display device according to another embodiment. The embodiment shown in FIG. 9 differs from that shown in FIG. 8 in that the auxiliary electrode AXE is disposed between the first bank BN1 and the pixel defining layer PDL. The description of FIG. 6 may be equally applied to the auxiliary electrode AXE.

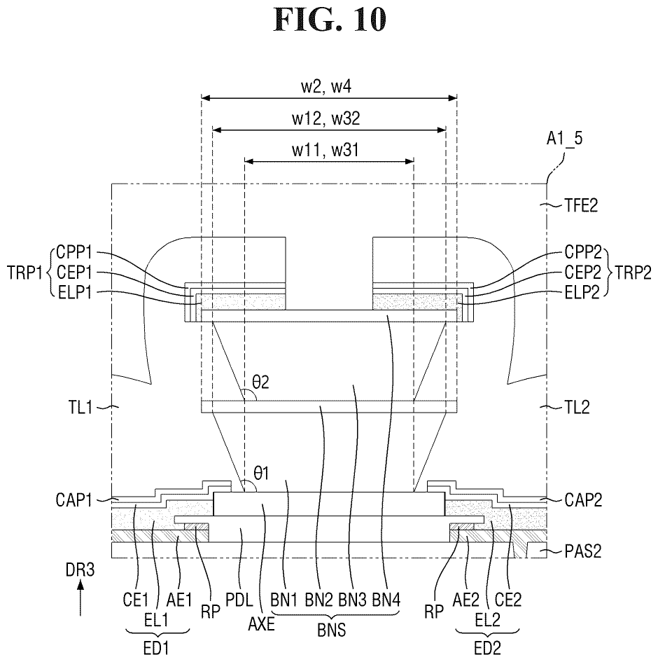

FIG. 10 is an enlarged view illustrating a display device according to another embodiment. The embodiment shown in FIG. 10 differs from that shown in FIG. 9 in that the common electrodes CE1, CE2, and CE3 are not in contact with the first bank BN1 and ends of the common electrodes CE1, CE2, and CE3 are spaced apart from the side surfaces of the first bank BN1. As described above with reference to FIG. 7, the common electrodes CE1, CE2, and CE3 spaced apart from one another may be electrically connected to one another through the auxiliary electrode AXE.

Referring to FIG. 4, the display device 10 may include trace patterns TRP1, TRP2, and TRP3, which become traces of the deposition process, on the bank structure BNS. The trace patterns TRP1, TRP2, and TRP3 may include light emitting patterns ELP1, ELP2, and ELP3, electrode patterns CEP1, CEP2, and CEP3, and capping patterns CPP1, CPP2, and CPP3, and may surround (e.g., may extend around) outer edges of the light emission areas EA1, EA2, and EA3 on the second bank BN2.

The trace patterns TRP1, TRP2, and TRP3 may be traces formed when the deposition material is disconnected from the light emitting layers EL1, EL2, and EL3, the common electrodes CE1, CE2, and CE3, and the capping layers CAP1, CAP2, and CAP3 in the light emission areas EA1, EA2, and EA3 by the tip of (or formed by) the bank structure BNS. When the light emitting material is entirely deposited, the light emitting layers EL1, EL2, and EL3 are formed in the openings, and light emitting patterns ELP1, ELP2, and ELP3 are formed on the bank structures BNS. The light emitting patterns ELP1, ELP2, and ELP3 are disconnected from the light emitting layers EL1, EL2, and EL3 by the tip of the bank structures BNS. Similarly, the common electrodes CE1, CE2, and CE3 and/or the electrode patterns CEP1, CEP2, and CEP3 and the capping layers CAP1, CAP2, and CAP3 and/or the capping patterns CPP1, CPP2, and CPP3 may be disconnected by the tip, and their traces may remain on the bank structure BNS. The trace patterns TRP1, TRP2, and TRP3 may be formed by patterning of each of the light emission areas EA1, EA2, and EA3 or by patterning around the opening.

The display device 10 may include light emitting patterns ELP1, ELP2, and ELP3 disposed above the bank structure BNS. The light emitting patterns EL1, ELP2, and ELP3 may include a first light emitting pattern ELP1, a second light emitting pattern ELP2, and a third light emitting pattern ELP3, which are disposed on the second bank BN2 of the bank structure BNS.

The first light emitting pattern ELP1 may include the same material as that of the first light emitting layer EL1 of the first light emitting element ED1, the second light emitting pattern ELP2 may include the same material as that of the second light emitting layer EL2 of the second light emitting element ED2, and the third light emitting pattern ELP3 may include the same material as that of the third light emitting layer EL3 of the third light emitting element ED3. Each of the light emitting patterns ELP1, ELP2, and ELP3 may be formed in (or during) the process of forming the light emitting layers EL1, EL2, and EL3 including the same material and may be disposed to be adjacent to the light emission areas EA1, EA2, and EA3 in which the light emitting layers EL1, EL2, and EL3 are respectively disposed.

The display device 10, according to one embodiment, may include a plurality of electrode patterns CEP1, CEP2, and CEP3 disposed on the bank structure BNS, and the plurality of electrode patterns CEP1, CEP2, and CEP3 may include the same material as that of the common electrodes CE1, CE2, and CE3. The first electrode pattern CEP1, the second electrode pattern CEP2, and the third electrode pattern CEP3 may be disposed directly on the first light emitting pattern ELP1, the second light emitting pattern ELP2, and the third light emitting pattern ELP3, respectively. The arrangement relationship of the electrode patterns CEP1, CEP2, and CEP3 and the light emitting patterns ELP1, ELP2, and ELP3 may be the same as the arrangement relationship of the light emitting layers EL1, EL2, and EL3 and the common electrodes CE1, CE2, and CE3.

The display device 10 may include capping patterns CPP1, CPP2, and CPP3 disposed above the bank structure BNS. The first capping pattern CPP1, the second capping pattern CPP2, and the third capping pattern CPP3 may be disposed directly on the first electrode pattern CEP1, the second electrode pattern CEP2, and the third electrode pattern CEP3, respectively. The arrangement relationship of the capping patterns CPP1, CPP2, and CPP3 and the electrode patterns CEP1, CEP2, and CEP3 may be the same as the arrangement relationship of the common electrodes CE1, CE2, and CE3 and the capping layers CAP1, CAP2, and CAP3.

The thin film encapsulation layer TFEL may be disposed on the light emitting elements ED1, ED2, and ED3 and the bank structure BNS and may cover the plurality of light emitting elements ED1, ED2, and ED3 and the bank structure BNS. The thin film encapsulation layer TFEL may include at least one inorganic film to prevent oxygen or moisture from permeating into the light emitting element layer EML. The thin film encapsulation layer TFEL may include at least one organic film to protect the light emitting element layer EML from particles, such as dust.

In an embodiment, the thin film encapsulation layer TFEL may include a lower inorganic encapsulation layer TFE1, an organic encapsulation layer TFE2, and an upper inorganic encapsulation layer TFE3, which are sequentially stacked on each other.

Each of the lower inorganic encapsulation layer TFE1 and the upper inorganic encapsulation layer TFE3 may include one or more inorganic insulation materials. The inorganic insulating material may be any one of silicon oxide, silicon nitride, and silicon oxynitride and may be, for example, aluminum oxide, titanium oxide, tantalum oxide, hafnium oxide, zinc oxide, silicon oxide, silicon nitride, and/or silicon oxynitride.

The organic encapsulation layer TFE2 may include a polymer-based material. The polymer-based material may include an acrylic-based resin, an epoxy-based resin, polyimide, and polyethylene. For example, the organic encapsulation layer TFE2 may include an acrylic-based resin, for example, polymethyl methacrylate, polyacrylic acid, etc. The organic encapsulation layer TFE2 may be formed by hardening a monomer or coating a polymer.

The lower inorganic encapsulation layer TFE1 may be disposed on the light emitting elements ED1, ED2, and ED3, the trace patterns TRP1, TRP2, and TRP3 and the bank structure BNS. The lower inorganic encapsulation layer TFE1 may include a first inorganic layer TL1, a second inorganic layer TL2, and a third inorganic layer TL3, which are disposed to correspond to the different light emission areas EA1, EA2, and EA3, respectively. Each of the first inorganic layer TL1, the second inorganic layer TL2, and the third inorganic layer TL3 may include an inorganic insulating material to cover the light emitting elements ED1, ED2, and ED3. The first inorganic layer TL1, the second inorganic layer TL2, and the third inorganic layer TL3 may prevent the light emitting elements ED1, ED2, and ED3 from being damaged from the external air.

The lower inorganic encapsulation layers TFE1 (TL1, TL2, and TL3) may be formed through a chemical vapor deposition (CVD) method and, thus, may be formed along a step difference of the deposited layers. For example, the first inorganic layer TL1, the second inorganic layer TL2, and the third inorganic layer TL3 may form a thin film even under the undercut due to (or formed by) the tip of the bank structure BNS. The lower inorganic encapsulation layers TL1, TL2, and TL3 may be disposed on the light emitting elements ED1, ED2, and ED3, the electrode patterns CEP1, CEP2, and CEP3 and the bank structures BNS. The first inorganic layer TL1 may be disposed along side surfaces adjacent to the first light emitting element ED1, the first capping layer CAP1, and the first common electrode CE1 of the first bank BN1 to cover them and may be disposed to cover the first light emitting pattern ELP1, the first electrode pattern CEP1, and the first capping pattern CPP1 by passing through (or extending along) the side surfaces of the second bank BN2.

The first inorganic layer TL1 does not overlap the second light emitting element ED2 and the third light emitting element ED3 and may be disposed only on the first light emitting element ED1 and the bank structure BNS near the first light emitting element ED1. The second inorganic layer TL2 does not overlap the first light emitting element ED1 and the third light emitting element ED3 and may be disposed only on the second light emitting element ED2 and the bank structure BNS near the second light emitting element ED2. The third inorganic layer TL3 does not overlap the first light emitting element ED1 and the second light emitting element ED2 and may be disposed only on the third light emitting element ED3 and the bank structure BNS near the third light emitting element ED3.

The first inorganic layer TL1 may be formed after the first common electrode CE1 is formed, the second inorganic layer TL2 may be formed after the second common electrode CE2 is formed, and the third inorganic layer TL3 may be formed after the third common electrode CE3 is formed. The first inorganic layer TL1, the second inorganic layer TL2, and the third inorganic layer TL3 may be disposed to be spaced apart from one another on the bank structure BNS. Therefore, a portion of the second bank BN2 or the fourth bank BN4 may not overlap the first to third inorganic layers TL1, TL2, and TL3, and a portion of the upper surface of the second bank BN2 or the fourth bank BN4 may be exposed without being covered by the first to third inorganic layers TL1, TL2, and TL3 in the spaces from among the first to third inorganic layers TL1, TL2, and TL3. The exposed upper surface of the second bank BN2 or the fourth bank BN4 may be directly in contact with the organic encapsulation layer TFE2 of the thin film encapsulation layer TFEL.

Referring to FIGS. 3 and 4, each of the first inorganic layer TL1, the second inorganic layer TL2, and the third inorganic layer TL3 may have a boundary on outer side surfaces of the light emission areas EA1, EA2, and EA3 in which the light emitting elements ED1, ED2, and ED3 are disposed. The first to third trace patterns TRP1, TRP2, and TRP3 may have a ring shape in a plan view. The trace patterns TRP1, TRP2, and TRP3 may be positioned on the tip of the second bank BN2 and may have an inner boundary adjacent to the light emission areas EA1, EA2, and EA3 and an outer boundary farther away from the light emission areas EA1, EA2, and EA3 than the inner boundary while being positioned between the light emission areas EA1, EA2, and EA3. When the electrode patterns CEP1, CEP2, and CEP3 and the light emitting patterns ELP1, ELP2, and ELP3 of the trace patterns TRP1, TRP2, and TRP3 are removed, the outer boundary of the trace patterns TRP1, TRP2, and TRP3 may be changed by adjusting the etching process. The outer boundary of the trace patterns TRP1, TRP2, and TRP3 may be matched with or adjacent to the boundary of the lower inorganic encapsulation layers TL1, TL2, and TL3. In one embodiment, the outer boundary of the trace patterns TRP1, TRP2, and TRP3 may be positioned to be more adjacent to the light emission areas EA1, EA2, and EA3 than the boundary of the lower inorganic encapsulation layers TL1, TL2, and TL3.

The organic encapsulation layer TFE2 is disposed on the second bank BN2 and the lower inorganic encapsulation layers TL1, TL2, and TL3. A portion of the organic encapsulation layer TFE2 may be in contact with the second bank BN2 or the fourth bank BN4.

The upper inorganic encapsulation layer TFE3 may be disposed on the organic encapsulation layer TFE2. The upper inorganic encapsulation layer TFE3 may include aluminum oxide, titanium oxide, tantalum oxide, hafnium oxide, zinc oxide, silicon oxide, silicon nitride, and/or silicon oxynitride.

A light blocking layer may be selectively disposed on the thin film encapsulation layer TFEL. The light blocking layer may be positioned among the light emission areas EA1, EA2, and EA3. The light blocking layer may include a light absorbing material. For example, the light blocking layer may include an inorganic black pigment or an organic black pigment. The inorganic black pigment may be carbon black, and the organic black pigment may include at least one of lactam black, perylene black, and aniline black, but they are not limited thereto. The light blocking layer may prevent color mixture from occurring due to permeation of visible light from among the first to third light emission areas EA1, EA2, and EA3, thereby improving color reproduction of the display device 10.

The display device 10 may include a plurality of color filters CF1, CF2, and CF3 disposed on the light emission areas EA1, EA2, and EA3. Each of the plurality of color filters CF1, CF2, and CF3 may have a filtering pattern area and a light blocking area. The filtering pattern area may be formed to overlap the light emission areas EA1, EA2, and EA3 or the opening in the bank structure BNS and may form a light output area from which the light emitted from the light emission areas EA1, EA2, and EA3 is output. The light blocking area is an area in which the plurality of color filters CF1, CF2, and CF3 are stacked so that light cannot be transmitted therethrough.

The color filters CF1, CF2, and CF3 may include a first color filter CF1, a second color filter CF2, and a third color filter CF3, which are disposed to correspond to the different light emission areas EA1, EA2, and EA3, respectively. The color filters CF1, CF2, and CF3 may include a colorant, such as a dye or pigment, for absorbing light of another wavelength band other than light of a specific wavelength band and may be disposed to correspond to colors of light emitted from the light emission areas EA1, EA2, and EA3. For example, the first color filter CF1 may be a red color filter disposed to overlap the first light emission area EA1 and transmitting only first light of a red color. The second color filter CF2 may be a green color filter disposed to overlap the second light emission area EA2 and transmitting only second light of a green color. The third color filter CF3 may be a blue color filter disposed to overlap the third light emission area EA3 and transmitting only third light of a blue color.

The display device 10 may reduce the intensity of reflective (or reflected) light due to external light because the color filters CF1, CF2, and CF3 are disposed to overlap one another. Furthermore, a color sense of the reflective light due to external light may be controlled by adjustment of layout, shape, area, and the like of the color filters CF1, CF2, and CF3 on a plan view.

An overcoat layer OC may be disposed on the color filters CF1, CF2, and CF3 to planarize upper ends (or upper surfaces) of the color filters CF1, CF2, and CF3. The overcoat layer OC may be a colorless light-transmissive layer having no color in a visible light band. For example, the overcoat layer OC may include a colorless light-transmissive organic material, such as an acrylic resin.

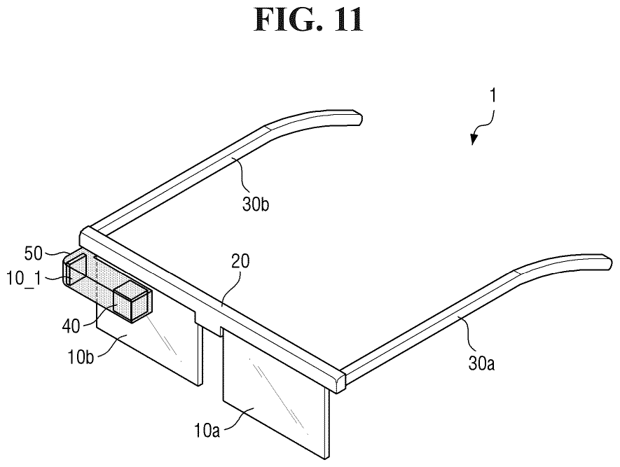

FIG. 11 is a view illustrating a virtual reality device including a display device according to one embodiment. A display device 10_1 shown in FIG. 11 may include the display device according to any of the above-described embodiments described with reference to FIGS. 1 to 10.

Referring to FIG. 11, the virtual reality device 1 may be a glasses-type display. The virtual reality device 1 may include the display device 10_1, a left-eye lens 10a, a right-eye lens 10b, a support frame 20, glasses frame legs 30a and 30b, a reflective member 40, and a display device accommodating portion 50.

In some embodiments, the virtual reality device 1 may be applied to a head mounted display (HMD) that includes a head mounting band, which may be mounted on a head, instead of the glasses frame legs 30a and 30b. Therefore, the virtual reality device 1 is applicable to various electronic devices in various forms.

The display device accommodating portion 50 may include the display device 10_1 and the reflective member 40. An image displayed on the display device 10_1 may be reflected by the reflective member 40 and provided to a user's right eye through the right-eye lens 10b. Therefore, the user may view a virtual reality (or augmented reality) image displayed on the display device 10_1 through the right eye.

The display device accommodating portion 50 may be disposed at a right end of the support frame 20, but its position is not limited thereto. For example, the display device accommodating portion 50 may be disposed at a left end of the support frame 20, and in such an embodiment, the image displayed on the display device 10_1 may be reflected by the reflective member 40 and provided to the user's left eye through the left-eye lens 10a. Therefore, the user may view the virtual reality image displayed on the display device 10_1 through the left eye.

As another example, the display device accommodating portion 50 may be disposed at both the left end and the right end of the support frame 20, and in such an embodiment, the user may view the virtual reality image displayed on the display device 10_1 through both the left eye and the right eye.

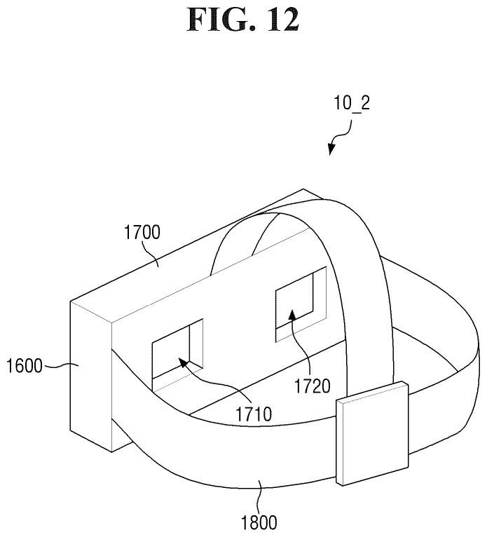

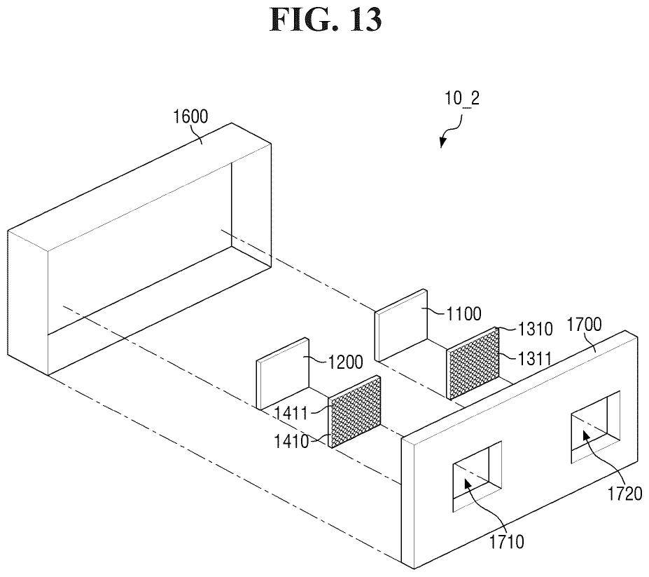

FIGS. 12 and 13 are views illustrating a head-mounted display device including a display device according to one embodiment. The display device 10_2 shown in FIGS. 12 and 13 may include the display device according to any of the embodiment described above with reference to FIGS. 1 to 10.

Referring to FIGS. 12 and 13, the display device 10_2 may be applied to a head mounted display (HMD) device. A first display device 1100 may provide an image to the user's right eye, and a second display device 1200 may provide an image to the user's left eye.

A first lens array 1310 may be disposed between the first display device 1100 and an accommodating portion cover 1700. The first lens array 1310 may include a plurality of lenses 1311. The plurality of lenses 1311 may include convex lenses convex toward the accommodating portion cover 1700.

The second lens array 1410 may be disposed between the second display device 1200 and the accommodating portion cover 1700. The second lens array 1410 may include a plurality of lenses 1411. The plurality of lenses 1411 may include convex lenses convex toward the accommodating portion cover 1700.

A display panel accommodating portion 1600 may accommodate the first display device 1100, the second display device 1200, the first lens array 1310, and the second lens array 1410. One surface of the display panel accommodating portion 1600 may be open to accommodate the first display device 1100, the second display device 1200, the first lens array 1310, and the second lens array 1410.

The accommodating portion cover 1700 may cover the open surface of the display panel accommodating portion 1600. The accommodating portion cover 1700 may have a first opening 1710 in which the user's left eye is arranged and a second opening 1720 in which the user's right eye is arranged. For example, the first opening 1710 and the second opening 1720 may be formed in a rectangular shape, but their shapes are not limited thereto. As another example, the first and second openings 1710 and 1720 may be formed in a circular or oval shape. As another example, the first and second openings 1710 and 1720 may be formed as one, single opening.

The first opening 1710 may be aligned with the first display device 1100 and the first lens array 1310, and the second opening 1720 may be aligned with the second display device 1200 and the second lens array 1410. Therefore, the user may view the image of the first display device 1100 virtually enlarged by the first lens array 1310 through the first opening 1710 and may view the image of the second display device 1200 virtually enlarged by the second lens array 1410 through the second opening 1720.

A head mounting band 1800 may fix the display panel accommodating portion 1600 to the head of the user so that the first opening 1710 and the second opening 1720 of the accommodating portion cover 1700 are respectively disposed in the user's left and right eyes. The head mounting band 1800 may be connected to an upper surface, a left side, and a right side of the display panel accommodating portion 1600.

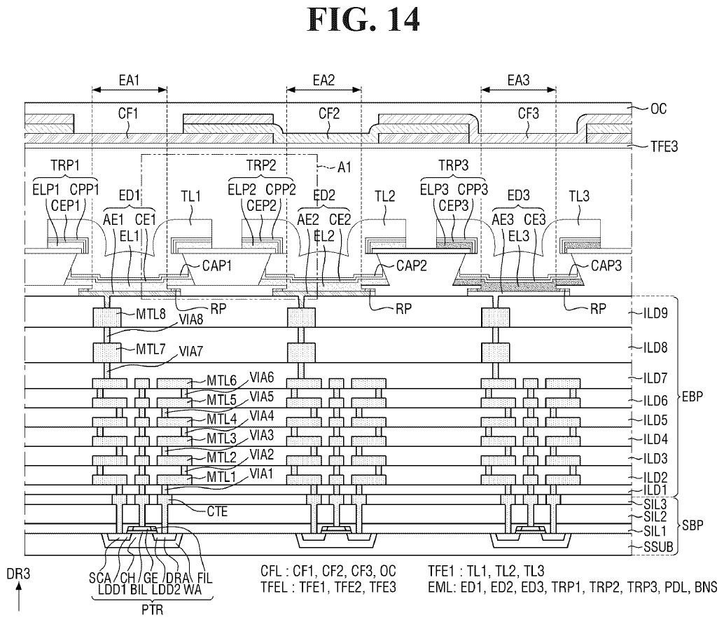

FIG. 14 is a cross-sectional view illustrating pixels according to one embodiment in the display device shown in FIGS. 11 to 13. The display device shown in FIG. 14 may include the light emitting element layer EML, the thin film encapsulation layer TFEL, and the color filter layer CFL shown in FIG. 4 and the same elements as those described above will be briefly described or may not be repeatedly described.

Referring to FIG. 14, the display panel may include a semiconductor backplane SBP, a light emitting backplane EBP, a light emitting element layer EML, a thin film encapsulation layer TFEL, and a color filter layer CFL.

The semiconductor backplane SBP may include a semiconductor substrate SSUB, first to third semiconductor insulating layers SIL1, SIL2, and SIL3, and a contact terminal CTE.

The semiconductor substrate SSUB may be a silicon substrate, a germanium substrate, or a silicon-germanium substrate. The semiconductor substrate SSUB may be a substrate doped with first type impurities. A plurality of well areas WA may be disposed on (or formed in) an upper surface of the semiconductor substrate SSUB. The plurality of well areas WA may be areas doped with second type impurities different from the first type impurities. For example, when the first type impurities are p-type impurities, the second type impurities may be n-type impurities. As another example, when the first type impurities are n-type impurities, the second type impurities may be p-type impurities.

The semiconductor substrate SSUB may include a plurality of pixel transistors PTR. The pixel transistor PTR may include the well area WA, a source area SCA, a drain area DRA, a channel area CH, a first lightly doped impurity area LDD1, a second lightly doped impurity area LDD2, a lower insulating layer BIL, a gate electrode GE, and a side insulating layer FIL.

The well area WA may be disposed on an upper portion of the semiconductor substrate SSUB. The well area WA may accommodate a source area SCA, a drain area DRA, a channel area CH, a first lightly doped impurity area LDD1, and a second lightly doped impurity area LDD2.

The source area SCA may correspond to a source electrode of the pixel transistor PTR, and the drain area DRA may correspond to a drain electrode of the pixel transistor PTR. Each of the source area SCA and the drain area DRA may be doped with the first type impurities. The source area SCA may be disposed at one side of the gate electrode GE, and the drain area SA may be disposed at the other side of the gate electrode GE.

The channel area CH may be disposed between the source area SCA and the drain area DRA. The lower insulating layer BIL may be disposed on the channel area CH to insulate the channel area CH and the gate electrode GE from each other. The gate electrode GE may be disposed on the lower insulating layer BIL. The gate electrode GE may overlap the channel area CH and the well area WA in the thickness direction. The side insulating layer FIL may be disposed on side surfaces of the gate electrode GE and an upper surface of the lower insulating layer BIL.

The first lightly doped impurity area LDD1 may be disposed between the channel area CH and the source area SCA, and the second lightly doped impurity area LDD2 may be disposed between the channel area CH and the drain area DRA. The first lightly doped impurity area LDD1 may have an impurity concentration lower than that of the source area SCA due to the lower insulating layer BIL. The second lightly doped impurity area LDD2 may have an impurity concentration lower than that of the drain area DRA by the lower insulating layer BIL. A distance between the source area SCA and the drain area DRA may be increased by the first lightly doped impurity area LDD1 and the second lightly doped impurity area LDD2. Therefore, because a length of the channel area CH of the pixel transistor PTR may be increased, punch-through and hot carrier due to a short channel may be avoided.

The first semiconductor insulating layer SIL1 may be disposed on the semiconductor substrate SSUB. The first semiconductor insulating layer SIL1 may include an inorganic film of silicon carbon nitride (SiCN) or silicon oxide (SiOₓ) but is not limited thereto.

The second semiconductor insulating layer SIL2 may be disposed on the first semiconductor insulating layer SIL1. The second semiconductor insulating layer SIL2 may include an inorganic film of silicon oxide (SiOₓ) but is not limited thereto.

The plurality of contact terminals CTE may be disposed on the second semiconductor insulating layer SIL2. The contact terminal CTE may be connected to one of the gate electrode GE, the source area SCA, and the drain area DRA of the pixel transistor PTR through a hole (e.g., an opening) passing through the first semiconductor insulating layer SIL1 and the second semiconductor insulating layer SIL2. The contact terminal CTE may include at least one of copper (Cu), aluminum (Al), tungsten (W), molybdenum (Mo), chromium (Cr), gold (Au), titanium (Ti), nickel (Ni), and neodymium (Nd).

The third semiconductor insulating layer SIL3 may be disposed on side surfaces of each of the plurality of contact terminals CTE. An upper surface of each of the plurality of contact terminals may be exposed without being covered by the third semiconductor insulating layer SIL3. The third semiconductor insulating layer SIL3 may include an inorganic film of silicon oxide (SiOₓ) but is not limited thereto.

The light emitting backplane EBP may include first to eighth metal layers MTL1 to MTL8, first to eighth vias VIA1 to VIA8, and first to ninth interlayer insulating layers ILD1 to ILD9.

The first to eighth metal layers MTL1 to MTL8 may be electrically connected to the contact terminals CTE exposed from the semiconductor backplane SBP to constitute a pixel circuit. For example, the semiconductor backplane SBP may include a plurality of pixel transistors PTR, and the light emitting backplane EBP may include a connection electrode for connecting the pixel transistors PTR and at least one capacitor connected to the pixel transistor PTR. The light emitting backplane EBP may electrically connect the pixel circuit with the first light emitting element ED1.

The first interlayer insulating layer ILD1 may be disposed on the semiconductor backplane SBP. The first via VIA1 may be connected to the contact terminal CTE exposed from the semiconductor backplane SBP by passing through the first interlayer insulating layer ILD1. The first metal layer MTL1 may be disposed on the first interlayer insulating layer ILD1 and thus connected to the first via VIA1.

The second interlayer insulating layer ILD2 may be disposed on the first interlayer insulating layer ILD1 and the first metal layer MTL1. The second via VIA2 may be connected to the first metal layer MTL1 through the second interlayer insulating layer ILD2. The second metal layer MTL2 may be disposed on the second interlayer insulating layer ILD2 and thus connected to the second via VIA2.

The third interlayer insulating layer ILD3 may be disposed on the second interlayer insulating layer ILD2 and the second metal layer MTL2. The third via VIA3 may be connected to the second metal layer MTL2 by passing through the third interlayer insulating layer ILD3. The third metal layer MTL3 may be disposed on the third interlayer insulating layer ILD3 and thus connected to the third via VIA3.

The fourth interlayer insulating layer ILD4 may be disposed on the third interlayer insulating layer ILD3 and the third metal layer MTL3. The fourth via VIA4 may be connected to the third metal layer MTL3 by passing through the fourth interlayer insulating layer ILD4. The fourth metal layer MTL4 may be disposed on the fourth interlayer insulating layer ILD4 and thus connected to the fourth via VIA4.

The fifth interlayer insulating layer ILD5 may be disposed on the fourth interlayer insulating layer ILD4 and the fourth metal layer MTL4. The fifth via VIA5 may be connected to the fourth metal layer MTL4 by passing through the fifth interlayer insulating layer ILD5. The fifth metal layer MTL5 may be disposed on the fifth interlayer insulating layer ILD5 and thus connected to the fifth via VIA5.

The sixth interlayer insulating layer ILD6 may be disposed on the fifth interlayer insulating layer ILD5 and the fifth metal layer MTL5. The sixth via VIA6 may be connected to the fifth metal layer MTL5 by passing through the sixth interlayer insulating layer ILD6. The sixth metal layer MTL6 may be disposed on the sixth interlayer insulating layer ILD6 and thus connected to the sixth via VIA6.

The seventh interlayer insulating layer ILD7 may be disposed on the sixth interlayer insulating layer ILD6 and the sixth metal layer MTL6. The seventh via VIA7 may be connected to the sixth metal layer MTL6 by passing through the seventh interlayer insulating layer ILD7. The seventh metal layer MTL7 may be disposed on the seventh interlayer insulating layer ILD7 and thus connected to the seventh via VIA7.

The eighth interlayer insulating layer ILD8 may be disposed on the seventh interlayer insulating layer ILD7 and the seventh metal layer MTL7. The eighth via VIA8 may be connected to the seventh metal layer MTL7 by passing through the eighth interlayer insulating layer ILD8. The eighth metal layer MTL8 may be disposed on the eighth interlayer insulating layer ILD8 and thus connected to the eighth via VIA8. The ninth interlayer insulating layer ILD9 may be disposed on the eighth interlayer insulating layer ILD8 and the eighth metal layer MTL8.

The first to eighth metal layers ML1 to ML8 and the first to eighth vias VIA1 to VIA8 may include substantially the same material. The first to eighth metal layers ML1 to ML8 and the first to eighth vias VIA1 to VIA8 may include at least one of copper (Cu), aluminum (Al), tungsten (W), molybdenum (Mo), chromium (Cr), gold (Au), titanium (Ti), nickel (Ni), and neodymium (Nd). The first to ninth interlayer insulating layers ILD1 to ILD9 may include an inorganic film of silicon oxide (SiOₓ) but are not limited thereto.

A thickness of the first metal layer MTL1, a thickness of the second metal layer MTL2, a thickness of the third metal layer MTL3, a thickness of the fourth metal layer MTL4, a thickness of the fifth metal layer MTL5, and a thickness of the sixth metal layer MTL6 may be greater than a thickness of the first via VIA1, a thickness of the second via VIA2, a thickness of the third via VIA3, a thickness of the fourth via VIA4, a thickness of the fifth via VIA5, and a thickness of the sixth via VIA6, respectively. Each of the thickness of the second metal layer MTL2, the thickness of the third metal layer MTL3, the thickness of the fourth metal layer MTL4, the thickness of the fifth metal layer MTL5, and the thickness of the sixth metal layer MTL6 may be greater than the thickness of the first metal layer MTL1. The thickness of the second metal layer MTL2, the thickness of the third metal layer MTL3, the thickness of the fourth metal layer MTL4, the thickness of the fifth metal layer MTL5, and the thickness of the sixth metal layer MTL6 may be substantially the same as one another. For example, the thickness of the first metal layer MTL1 may be about 1360 Å, and each of the thickness of the second metal layer MTL2, the thickness of the third metal layer MTL3, the thickness of the fourth metal layer MTL4, the thickness of the fifth metal layer MTL5, and the thickness of the sixth metal layer MTL6 may be about 1440 Å. Each of the thickness of the first via VIA1, the thickness of the second via VIA2, the thickness of the third via VIA3, the thickness of the fourth via VIA4, the thickness of the fifth via VIA5, and the thickness of the sixth via VIA6 may be about 1150 Å.

Each of a thickness of the seventh metal layer MTL7 and a thickness of the eighth metal layer MTL8 may be greater than each of the thickness of the first metal layer MTL1, the thickness of the second metal layer MTL2, the thickness of the third metal layer MTL3, the thickness of the fourth metal layer MTL4, the thickness of the fifth metal layer MTL5, and the thickness of the sixth metal layer MTL6. Each of the thickness of the seventh metal layer MTL7 and the thickness of the eighth metal layer MTL8 may be greater than each of the thickness of the seventh via VIA7 and the thickness of the eighth via VIA8. Each of the thickness of the seventh via VIA 7 and the thickness of the eighth via VIA8 may be greater than each of the thickness of the first via VIA1, the thickness of the second via VIA2, the thickness of the third via VIA3, the thickness of the fourth via VIA 4, the thickness of the fifth via VIA5, and the thickness of the sixth via VIA6. The thickness of the seventh metal layer MTL7 and the thickness of the eighth metal layer MTL8 may be substantially the same as each other. For example, each of the thickness of the seventh metal layer MTL7 and the thickness of the eighth metal layer MTL8 may be about 9000 Å. Each of the thickness of the seventh via VIA7 and the thickness of the eighth via VIA8 may be about 6000 Å.

The display device may include a plurality of pixels in a relatively small area as resolution is increased. The light emitting backplane EBP may include the first to eighth metal layers MTL1 to MTL8 to implement the connection electrode for connecting the pixel transistors PTR and at least one capacitor connected to the pixel transistor PTR, thereby implementing the pixel circuit in a relatively small area. Therefore, the light emitting element layer EML may be formed on a silicon wafer that includes a semiconductor backplane SBP and a light emitting backplane EBP, and the display device may implement an image having an ultra-high resolution.

The light emitting element layer EML and the thin film encapsulation layer TFEL shown in FIGS. 5 to 10, which are described above, may be also applied to the light emitting element layer EML and the thin film encapsulation layer TFEL shown in FIG. 14.

In concluding the detailed description, those skilled in the art will appreciate that many variations and modifications can be made to the described embodiments without substantially departing from the present disclosure. Therefore, the disclosed embodiments of the present disclosure are used in a generic and descriptive sense and not for purposes of limitation.

What is claimed is:

1. A display device comprising:
a first pixel electrode on a substrate;
a first light emitting layer on the first pixel electrode;
a first common electrode on the first light emitting layer;
a first bank on the substrate and exposing the first common electrode therethrough; and
a second bank on the first bank and having side surfaces protruding beyond side surfaces of the first bank, a width of a lower surface of the first bank being smaller than that of an upper surface of the first bank.

2. The display device of claim 1, wherein the first common electrode is in contact with the side surfaces of the first bank.

3. The display device of claim 1, wherein an angle between the lower surface and the side surfaces of the first bank is greater than 90°.

4. The display device of claim 1, wherein the first bank comprises at least one of polysilicon, amorphous carbon, graphite, and graphene.

5. The display device of claim 1, wherein the second bank comprises at least one of SiOₓ, SiN_{y}, SiOₓN_{y}, and a metal.

6. The display device of claim 1, further comprising an auxiliary electrode between the substrate and the first bank.

7. The display device of claim 6, wherein the auxiliary electrode is in contact with the first common electrode.

8. The display device of claim 1, further comprising:
a third bank on the second bank; and
a fourth bank on the third bank and having side surfaces protruding beyond side surfaces of the third bank.

9. The display device of claim 8, wherein a width of a lower surface of the third bank is smaller than a width of an upper surface of the third bank and smaller than a width of the second bank.

10. The display device of claim 1, further comprising a first inorganic layer on the second bank and the first common electrode.

11. The display device of claim 10, further comprising a first capping layer between the first common electrode and the first inorganic layer.

12. The display device of claim 10, further comprising:
a second pixel electrode on the substrate and spaced apart from the first pixel electrode;
a second light emitting layer on the second pixel electrode;
a second common electrode on the second light emitting layer and spaced apart from the first common electrode; and
a second inorganic layer on the second common electrode and the second bank and spaced apart from the first inorganic layer.

13. The display device of claim 10, further comprising:
a first light emitting pattern between the second bank and the first inorganic layer and comprising the same material as that of the first light emitting layer; and
a first electrode pattern between the first light emitting pattern and the first inorganic layer and comprising the same material as that of the first common electrode.

14. A display device comprising:
a first pixel electrode on a substrate;
a first light emitting layer on the first pixel electrode;
a first common electrode on the first light emitting layer;
a first bank on the substrate and exposing the first common electrode therethrough; and
a second bank on the first bank and comprising side surfaces protruding beyond side surfaces of the first bank,
wherein the first bank comprises at least one of polysilicon, amorphous carbon, graphite, and graphene, and
wherein the first common electrode is in contact with the side surfaces of the first bank.

15. The display device of claim 1, wherein the second bank comprises at least one of SiOₓ, SiN_{y}, SiOₓN_{y}, and a metal.

16. The display device of claim 14, further comprising a first inorganic layer on an upper surface of the first common electrode, the side surfaces of the first bank, and an upper surface and a lower surface of the second bank.

17. A display device comprising:
a first pixel electrode on a substrate;
a pixel defining layer on the substrate and exposing the first pixel electrode therethrough;
a first light emitting layer on the first pixel electrode;
a first common electrode on the first light emitting layer;
an auxiliary electrode on the pixel defining layer and in contact with the first common electrode;
a first bank on the auxiliary electrode; and
a second bank on the first bank and comprising side surfaces protruding beyond side surfaces of the first bank, a width of a lower surface of the first bank and a width of an upper surface of the first bank being different from each other.

18. The display device of claim 17, wherein the width of the lower surface of the first bank is smaller than that of the upper surface of the first bank.

19. The display device of claim 18, wherein a cross-sectional width of the first bank reduces from the upper surface toward the lower surface.

20. The display device of claim 17, wherein the auxiliary electrode comprises at least one of copper, aluminum, and molybdenum.
